(19) United States
(12) Patent Application Publication
(10) Pub. No.: US 2025/0035693 A1
(43) Pub. Date: Jan. 30, 2025

(54) CONDITION MONITORING OF ELECTRICAL DEVICES

(71) Applicant: AUGURY SYSTEMS LTD., Haifa (IL)

(72) Inventors: Daniel BAR-NESS, Tirat HaCarmel (IL); Assaf BARAK, Haifa (IL); Gal SHAUL, Haifa (IL); Saar YOSKOVITZ, Haworth, NJ (US); Gideon KOGAN, Jerusalem (IL); Shahar RINOTT, Haifa (IL); Oren KOBO, Haifa (IL)

(73) Assignee: AUGURY SYSTEMS LTD., Haifa (IL)

(21) Appl. No.: 18/715,190

(22) PCT Filed: Dec. 1, 2022
(86) PCT No.: PCT/IL2022/051282

§ 371 Date: May 31, 2024

Related U.S. Application Data
(60) Provisional application No. 63/285,191, filed on Dec. 2, 2021.

(51) Int. Cl. G01R 31/08; G05B 13/04

(52) U.S. Cl. CPC G01R 31/088; G05B 13/042

(57) ABSTRACT

A method for monitoring and identifying electrical discharge generated by electrical devices including collecting output indications of at least one physical parameter related to electrical discharge and sensed from a plurality of electrical devices operating at a voltage at which electrical discharge may occur, generating a unified model representative of behavior of the plurality of electrical devices based at least on the output indications of the at least one physical parameter sensed from the plurality of electrical devices, applying the model to output indications of the at least one physical parameter sensed from at least one given electrical device operating at a voltage at which electrical discharge may occur, identifying, at least by the applying of the model, at least one electrical-discharge related condition of the given electrical device, and automatically providing a human sensible output notification including an indication of the at least one identified condition.

### RELATED APPLICATIONS

Reference is hereby made to U.S. Provisional Patent Application No. 63/285,191, entitled ‘CONTINUOUS MONITORING FOR HIGH VOLTAGE SYSTEMS’, filed Dec. 3, 2021, the disclosure of which is hereby incorporated by reference and priority of which is hereby claimed pursuant to 37 CFR 1.78(a)(4) and (5)(i).

### FIELD OF THE INVENTION

The present invention relates generally to condition monitoring of electrical devices and more specifically to monitoring of electrical discharge in electrical devices.

### BACKGROUND OF THE INVENTION

Various types of systems and methods for condition monitoring of electrical devices are known in the art.

### SUMMARY OF THE INVENTION

The present invention seeks to provide improved systems and methods for monitoring and detecting faults characterized by electrical discharge, such as partial discharge, in electrical devices.

There is thus provided in accordance with a preferred embodiment of the present invention a method for monitoring and identifying electrical discharge generated by electrical devices including collecting output indications of at least one physical parameter related to electrical discharge and sensed from a plurality of electrical devices operating at at least one voltage at which electrical discharge may occur, generating a unified model representative of behavior of the plurality of electrical devices based at least on the output indications of the at least one physical parameter sensed from the plurality of electrical devices, applying the model to output indications of the at least one physical parameter sensed from at least one given electrical device operating at at least one voltage at which electrical discharge may occur, identifying, at least by the applying of the model, at least one electrical-discharge related condition of the given electrical device, the identified condition including identification of at least one of the presence or absence of electrical discharge, a severity of the electrical discharge if present and a location of the electrical discharge if present and automatically providing a human sensible output notification including an indication of the at least one identified condition.

Preferably, the human sensible output notification also includes recommendation for adjustment of operating parameters of the at least one given electrical device based on the identified condition, the method further including automatically adjusting the operating parameters of the given electrical device in accordance with the recommendation, thereby alleviating the electrical discharge.

Preferably, the plurality of electrical devices and the given electrical device include high voltage (HV) electrical devices operating at a voltage of at least 1 kilovolt or a power of at least 1 MVA.

Preferably, the plurality of electrical devices includes a multiplicity of mutually different types of electrical devices and the unified model is representative of behavior of the mutually different types of electrical devices.

Preferably, the method also includes collecting operational condition data from the plurality of electrical devices and related to electrical discharge, the operational condition data being associated with corresponding ones of the output indications of the sensed physical parameters, wherein the generating the unified model is additionally based on the operational condition data associated with the output indications of the at least one sensed physical parameter.

Preferably, the generating the unified model includes training a machine learning model by providing thereto at least the output indications of the at least one sensed physical parameter and the applying the unified model includes providing the output indications of the at least one sensed physical parameter from the at least one given electrical device to the machine learning model, following the training thereof.

Preferably, the method also includes sensing, by a plurality of physical parameter sensors coupled to the plurality of electrical devices, the at least one physical parameter thereof, the plurality of physical parameter sensors providing the output indications of the at least one sensed physical parameter, at least one of the plurality of physical parameter sensors being coupled to the at least one given electrical device, for sensing the at least one physical parameter of the at least one given electrical device and providing output indications thereof.

Preferably, the electrical discharge includes partial discharge, the physical parameter sensed from the plurality of electrical devices is related to partial discharge, the plurality of electrical devices operating at at least one voltage at which partial discharge may occur, the at least one given electrical device operates at at least one voltage at which partial discharge may occur; and the identifying includes identifying, by the applying of the model, at least one partial-discharge related condition of the given electrical device, the identified condition including identification of at least one of the presence or absence of partial discharge, a severity of the partial discharge if present and a location of the partial discharge if present.

Preferably, the plurality of electrical devices and the at least one given electrical device include substantially no moving parts.

Preferably, the plurality of electrical devices and the at least one given electrical device are selected from a group including high power transformers, cables, breakers, switchgears, control equipment, electric panels, motor starters, variable frequency drives and insulators.

In accordance with one preferred embodiment of the present invention, the generating the model includes extracting, by implementation of cyclostationary analysis, at least one feature of the output indications of the at least one physical parameter of the plurality of electrical devices, the model being based on the at least one feature and the applying the model includes applying the model to at least one feature extracted, by implementation of cyclostationary analysis, from the output indications of the at least one physical parameter sensed from the at least one given electrical device, an accuracy of the identification of the presence or absence of electrical discharge in the given electrical device being improved due to the implementation of cyclostationary analysis.

Preferably, the output indication of the at least one physical parameter includes acoustic vibration signals.

In accordance with another preferred embodiment of the present invention, the output indications of the at least one physical parameter include signals, the generating the model includes backpropagating ones of the signals over respective distances until the signals become transform limited, the model being based at least on the transform limited backpropagated signals; and the applying the model includes applying the model to backpropagated, transform limited ones of the signals from the given electrical device, variation in characteristics of the signals from the plurality of electrical devices and the given electrical device, arising due to propagation of the signals within respective ones of the plurality of electrical devices and the given electrical device, being reduced as a result of the backpropagating, at least one of an accuracy and precision of the identified condition of the given electrical device being improved thereby.

Preferably, the output indications of the at least one physical parameter include output indications of at least two different physical parameters.

Preferably, the at least two different physical parameters include vibration and magnetic field.

Preferably, the applying the model includes fusing the output indications of the vibration over time and the output indications of the magnetic field over time, and applying the model to the fused output indications over time, wherein the output indication of the condition includes an indication of development of partial discharge based on trends in the fused output indications over time.

Preferably, the method also includes correcting the vibration output indications for dispersion effects due to propagation of the vibration output indications through at least one medium within the at least one electrical device.

Preferably, applying the model further includes placing, by at least one of backpropagating the vibration output indication and forward propagating the magnetic field output indication, the vibration output indication and the magnetic field output indication on a common timeline, finding a relative phase of the magnetic field output indication with respect to the vibration output indication along the common timeline and evaluating a severity of partial discharge based on the relative phase.

Preferably, the method also includes extracting a magnetic line frequency from the magnetic field output indication and filtering the magnetic field output indication based on the magnetic line frequency.

In accordance with a further preferred embodiment of the present invention, the method also includes finding a distance to a source of the vibration output indication based on the backpropagating the vibration output indication and finding a three-dimensional location of the source from which the vibration output indication originated based on output indications sensed by no more than three sensors and taking into account the distance.

There is further provided in accordance with another preferred embodiment of the present invention a method for monitoring and identifying electrical discharge of electrical devices, including receiving at least first and second signals respectively representing at least first and second physical parameters related to electrical discharge and sensed from at least one electrical device operating at at least one voltage at which electrical discharge may occur, transforming at least one of the at least first and second signals to generate at least one transformed signal having at least one characteristic in common with the other one of the at least first and second signals, fusing the first and second signals, wherein at least one of the first and second signals includes the transformed signal and providing a human sensible output indicative of an electrical-discharge related condition of the at least one electrical device, based on the fusing.

Preferably, the transforming includes at least one of backpropagating and forward propagating.

Preferably, the transforming includes backpropagating the at least one of the at least first and second signals until the at least one of the at least first and second signals becomes transform limited, and the at least one characteristic corresponds to a characteristic of the at least one transformed signal as originally generated at a source thereof.

Preferably, the at least first and second physical parameters include mutually different physical parameters.

Preferably, the first and second physical parameters include vibration and magnetic field.

Preferably, the transforming includes backpropagating the vibration signal over a time and a distance until the vibration signal becomes transform limited and the fusing includes placing the magnetic field signal and the transform limited vibration signal on a common timeline, finding a relative phase of the magnetic field signal with respect to the transform limited vibration signal along the common timeline, and evaluating a severity of electrical discharge based on the relative phase.

Preferably, the time at which the vibration signal becomes transform limited corresponds to a time at which the vibration signal was originally generated at the source thereof, the distance at which the vibration signal becomes transform limited corresponds to a distance between the source and a vibration sensor sensing the vibration signal and the human sensible output includes an indication of a location of electrical discharge in the given electrical device based on the distance to the source.

Preferably, the human sensible output also includes a recommendation for adjustment of operating parameters of the at least one electrical device based on the identified condition, the method further including automatically adjusting the operating parameters of the at least one electrical device in accordance with the recommendation, thereby alleviating the electrical discharge.

Preferably, the at least one electrical device includes at least one high voltage (HV) electrical device operating at a voltage of at least one kilovolt or an apparent power of at least one MVA.

In accordance with a preferred embodiment of the present invention, the at least one electrical device includes at least first and second electrical devices and the first and second signals are respectively sensed from the at least first and second electrical devices.

There is further provided in accordance with still another preferred embodiment of the present invention a system for monitoring and identifying electrical discharge generated by electrical devices including a plurality of sensors providing output indications of at least one physical parameter related to electrical discharge and sensed from a plurality of electrical devices operating at at least one voltage at which electrical discharge may occur, a signal analyzer operative to receive the output indications of the at least one physical parameter and to generate, at least based thereon, a unified model representative of behavior of the plurality of electrical devices, at least one sensor providing at least one output indication of the at least one physical parameter sensed from at least one given electrical device operating at at least one voltage at which electrical discharge may occur, the signal analyzer being operative to receive the at least one output indication of the at least one physical parameter sensed from the at least one given electrical device and to apply the model thereto, the signal analyzer being further operative to identify, by the application of the model, at least one electrical-discharge related condition of the given electrical device, the identified condition including identification of at least one of the presence or absence of electrical discharge, a severity of the electrical discharge if present and a location of the electrical discharge if present and a human-sensible notification module operative to automatically provide a human sensible output notification including an indication of the at least one identified condition.

Preferably, the human sensible output notification of the system also includes a recommendation for adjustment of operating parameters of the at least one given electrical device based on the identified condition, the system further including a control module operative to automatically adjust the operating parameters of the given electrical device in accordance with the recommendation, thereby alleviating the electrical discharge.

Preferably, the plurality of electrical devices and the given electrical device include high voltage (HV) electrical devices operating at a voltage of at least 1 kilovolt or a power of at least 1 MVA.

Preferably, the plurality of electrical devices includes a multiplicity of mutually different types of electrical devices and the unified model is representative of behavior of the mutually different types of electrical devices.

Preferably, the signal analyzer is also operative to collect operational condition data from the plurality of electrical devices and related to electrical discharge, the operational condition data being associated with corresponding ones of the output indications of the sensed physical parameters, wherein the unified model is generated additionally based on the operational condition data associated with the output indications of the at least one sensed physical parameter.

Preferably, the signal analyzer being operative to generate the unified model includes the signal analyzer being operative to train a machine learning model by way of providing thereto at least the output indications of the at least one sensed physical parameter and the signal analyzer being operative to apply the unified model includes the signal analyzer being operative to provide the output indications of the at least one sensed physical parameter from the at least one given electrical device to the machine learning model, once the machine learning model is trained.

Preferably, the signal analyzer is operative to dynamically update the machine learning model once the machine learning model is trained, as a result of the application of the machine learning model.

Preferably, the electrical discharge includes partial discharge, the physical parameter sensed from the plurality of electrical devices is related to partial discharge, the plurality of electrical devices operates at at least one voltage at which partial discharge may occur, the at least one given electrical device operates at at least one voltage at which partial discharge may occur and the signal analyzer is operative to identify, at least by the application of the model, at least one partial-discharge related condition of the given electrical device, the identified condition including identification of at least one of the presence or absence of partial discharge, a severity of the partial discharge if present and a location of the partial discharge if present.

Preferably, the plurality of electrical devices and the at least one given electrical device include substantially no moving parts.

Preferably, the plurality of electrical devices and the at least one given electrical device are selected from a group including high power transformers, cables, breakers, switchgears, control equipment, electric panels, motor starters, variable frequency drives and insulators.

Preferably, the signal analyzer being operative to generate the model includes the signal analyzer being operative to extract, by implementation of cyclostationary analysis, at least one feature of the output indications of the at least one physical parameter of the plurality of electrical devices, the model being based on the at least one feature and the application of the model includes application of the model to at least one feature extracted, by implementation of cyclostationary analysis, from the output indications of the at least one physical parameter sensed from the at least one given electrical device, an accuracy of the identification of the presence or absence of electrical discharge in the given electrical device being improved due to the implementation of cyclostationary analysis.

Preferably, the output indications of the at least one physical parameter include acoustic vibration signals.

Preferably, the output indications of the at least one physical parameter include signals, the signal analyzer being operative to generate the model includes the signal analyzer being operative to backpropagate ones of the signals over respective distances until the signals become transform limited, the model being based at least on the transform limited backpropagated signals and the application of the model includes application of the model to backpropagated, transform limited ones of the signals from the given electrical device, variation in characteristics of the signals from the plurality of electrical devices and the given electrical device, arising due to propagation of the signals within respective ones of the plurality of electrical devices and the given electrical device, being reduced as a result of the backpropagation, at least one of an accuracy and precision of the identified condition of the given electrical device being improved thereby.

Preferably, the output indications of the at least one physical parameter include output indications of at least two different physical parameters.

Preferably, the at least two different physical parameters include vibration and magnetic field.

Preferably, the application of the model includes fusion of the output indications of the vibration over time and the output indications of the magnetic field over time, and application of the model to the fused output indications over time, wherein the output indication of the condition includes an indication of development of partial discharge based on trends in the fused output indications over time.

Preferably, the signal analyzer is also operative to correct the vibration output indications for dispersion effects due to propagation of the vibration output indications through at least one medium within the at least one electrical device.

Preferably, the signal analyzer is further operative to place, by at least one of backpropagation of the vibration output indication and forward propagation of the magnetic field output indication, the vibration output indication and the magnetic field output indication on a common timeline, find a relative phase of the magnetic field output indication with respect to the vibration output indication along the common timeline and evaluate a severity of partial discharge based on the relative phase.

Preferably, the system also includes signal processing functionality for extraction of a magnetic line frequency from the magnetic field output indication and filtration of the magnetic field output indication based on the magnetic line frequency.

In accordance with a preferred embodiment of the system of the present invention, the signal analyzer is further operative to find a distance to a source of the vibration output indication based on the backpropagation of the vibration output indication and find a three-dimensional location of the source from which the vibration output indication originated based on output indications sensed by no more than three sensors and taking into account the distance.

There is additionally provided in accordance with yet another preferred embodiment of the present invention a system for monitoring and identifying electrical discharge of electrical devices, including signal transformation functionality operative to receive at least first and second signals respectively representing at least first and second physical parameters related to electrical discharge and sensed from at least one electrical device operating at at least one voltage at which electrical discharge may occur, transform at least one of the at least first and second signals to generate at least one transformed signal having at least one characteristic in common with the other one of the at least first and second signals, signal fusing functionality operative to fuse the first and second signals, wherein at least one of the first and second signals includes the transformed signal and a human sensible output module operative to provide a human sensible output indicative of an electrical-discharge related condition of the at least one electrical device, based on the fusing.

Preferably, the transform includes at least one of backpropagation and forward propagation.

Preferably, the transform includes backpropagation of the at least one of the at least first and second signals until the at least one of the at least first and second signals becomes transform limited, and the at least one characteristic corresponds to a characteristic of the at least one transformed signal as originally generated at a source thereof.

Preferably, the at least first and second physical parameters include mutually different physical parameters.

Preferably, the first and second physical parameters include vibration and magnetic field.

Preferably, the transform includes backpropagation of the vibration signal over a time and a distance until the vibration signal becomes transform limited and the fusing functionality is operative to place the magnetic field signal and the transform limited vibration signal on a common timeline, find a relative phase of the magnetic field signal with respect to the transform limited vibration signal along the common timeline, and evaluate a severity of electrical discharge based on the relative phase.

Preferably, the time at which the vibration signal becomes transform limited corresponds to a time at which the vibration signal was originally generated at the source thereof, the distance at which the vibration signal becomes transform limited corresponds to a distance between the source and a vibration sensor sensing the vibration signal and the human sensible output includes an indication of a location of electrical discharge in the given electrical device based on the distance to the source.

Preferably, the human sensible output also includes a recommendation for adjustment of operating parameters of the at least one electrical device based on the identified condition, the system further including a control module operative to automatically adjust the operating parameters of the at least one electrical device in accordance with the recommendation, thereby alleviating electrical discharge.

Preferably, the at least one electrical device includes at least one high voltage (HV) electrical device operating at a voltage of at least one kilovolt or an apparent power of at least one MVA.

In accordance with a preferred embodiment of the system of the present invention, the at least one electrical device includes at least first and second electrical devices and the first and second signals are respectively sensed from the at least first and second electrical devices.

### BRIEF DESCRIPTION OF THE DRAWINGS

The present invention will be understood and appreciated more fully based on the following detailed description taken in conjunction with the drawings in which:

FIG. 1 is a simplified schematic block diagram illustration of a system for monitoring of electrical devices, constructed and operative in accordance with a preferred embodiment of the present invention;

FIGS. 2A and 2B are simplified schematic block diagram illustrations respectively showing training and operation of a model useful within a system of the type shown in FIG. 1;

FIG. 3 is a simplified schematic block diagram illustration of operation of another model useful within a system of the type shown in FIG. 1;

FIG. 4 is a simplified flow chart illustrating steps in a method for monitoring of electrical devices, as may be carried out by a system of the type shown in FIG. 1;

FIGS. 5A and 5B are respective graphs illustrating outputs of cyclostationary signal processing useful in conjunction with any of FIGS. 1-4;

FIGS. 6A-6C are respective graphs showing relative trends in signals over time, useful in conjunction with the system and method of any of FIGS. 1-4;

FIG. 7 is a simplified schematic block diagram illustration of a system for monitoring of electrical devices, constructed and operative in accordance with another preferred embodiment of the present invention;

FIG. 8 is a highly simplified schematic illustration of propagation of an acoustic emission signal arising from electrical discharge in an electrical device;

FIGS. 9A and 9B re simplified respective graphs illustrating fusing of signals indicative of electrical discharge in electrical devices, in accordance with one preferred embodiment of the present invention;

FIGS. 10A, 10B and 10C are simplified respective graphs illustrating fusing of signals indicative of electrical discharge in electrical devices, in accordance with another preferred embodiment of the present invention;

FIG. 11 is a simplified flow chart illustrating a method for monitoring of electrical devices, in accordance with a preferred embodiment of the present invention;

FIG. 12 is a simplified flow chart illustrating a method for monitoring of electrical devices, in accordance with another preferred embodiment of the present invention;

FIG. 13 is a simplified flow chart illustrating a method for monitoring of electrical devices, in accordance with yet another preferred embodiment of the present invention; and

FIG. 14 is a simplified flow chart illustrating a method for monitoring of electrical devices, in accordance with still another preferred embodiment of the present invention.

### DETAILED DESCRIPTION OF PREFERRED EMBODIMENTS

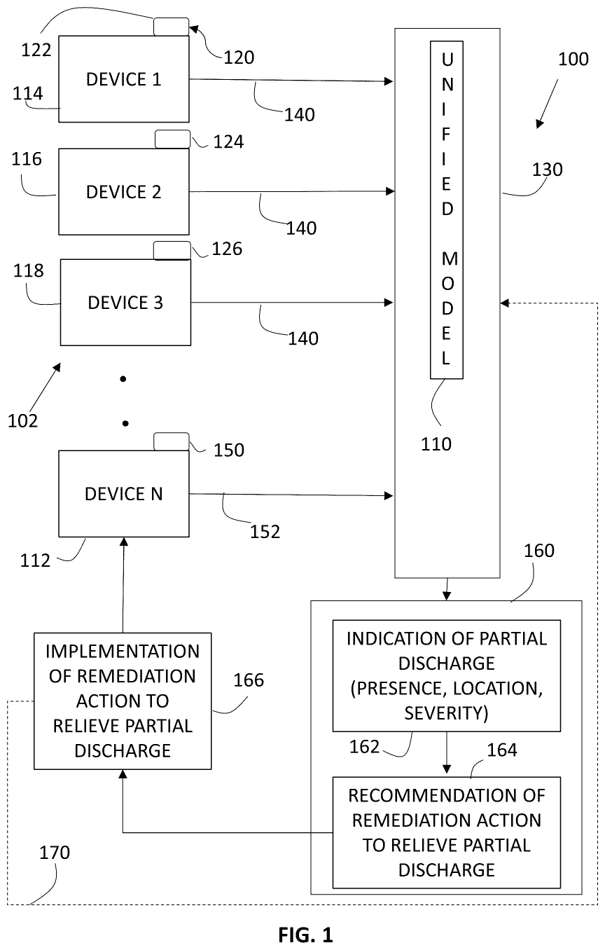

Reference is now made to FIG. 1, which is a simplified schematic block diagram illustration of a system for monitoring of electrical devices, constructed and operative in accordance with a preferred embodiment of the present invention.

As seen in FIG. 1, there is provided a system 100 for monitoring a condition of an electrical device. System 100 is preferably operative to collect output indications of at least one physical parameter sensed from a plurality of electrical devices 102, here shown to be embodied as devices 1-3. The at least one physical parameter is preferably at least one physical parameter from which may be derived a condition of electrical devices 1-3. The at least one physical parameter may be at least one physical parameter related to and hence indicative of electrical discharge which may occur in electrical devices 102 due to faults therein. By way of example, the at least one physical parameter may be at least one signal representing one or more of vibration, temperature, current, voltage, EM radiation, magnetic flux or magnetic field, oil humidity, dissolved gases. or other relevant physical parameters associated with electrical devices 102, as may be known in the art.

System 100 is preferably operative to create a model 110 representative of the behavior of the plurality of electrical devices, based at least on the output indications measured from the plurality of electrical devices 102. Model 110 generated by system 100 is preferably representative of behavior of the plurality of electrical devices with respect to fault development therein, particularly preferably with respect to partial discharge. Model 110 is preferably a unified model commonly representative of and applicable to the plurality of electrical devices 102 despite differences that may exist between the devices.

System 100 is preferably operative to additionally receive output indications of the at least one physical parameter sensed from at least one given electrical device 112, such as an electrical device N. Given electrical device N may or may not be a member of the group of devices 102 based on which unified model 110 was generated. System 100 is preferably operative to identify a condition, and, particularly preferably, at least one electrical-discharge related condition of the given electrical device N by applying the unified model 110 to the output indications obtained from the least one given electrical device N. System 100 is further preferably operative to provide a human-sensible output indication of the identified condition and optionally to automatically implement measures in response to the identified condition.

Preferred embodiments of the present invention, such as system 100 and unified model 110 forming a part thereof, relate to detection of electrical discharge in electrical equipment operating at voltages and/or apparent powers at which electrical discharge phenomena may occur. Such electrical equipment may be high voltage electrical equipment. By way of example only, system 100 may be used for condition monitoring of high voltage electrical equipment operating at voltages of at least one kilovolt and/or apparent powers of at least one MVA. By way of example, such high voltage electrical equipment may operate at voltages in the range of 1-1000 kilovolts and/or at powers of 1-1000 MVA. However, it is understood that electrical discharge and more particularly partial discharge may also be exhibited by electrical equipment operating at lower voltages and/or apparent powers and such electrical equipment is also included in the scope of equipment to which system 100 may be applicable.

While it is appreciated that the systems and methods of the present invention may be employed with respect to any suitable electrical equipment requiring fault monitoring during the operation thereof, systems and methods of the present invention find particular utility in fault detection based on monitoring and detection of partial discharge in high-power transformers. Accordingly, much of the description which follows relates to the use of the present invention in the context of monitoring and identifying partial discharge from transformers, including detecting the presence or absence of partial discharge, severity of partial discharge if present and location of partial discharge if present. It is appreciated, however, that the present invention is not limited to monitoring and detection of partial discharge from transformers and this is simply one preferred embodiment of the present invention.

Accurate identification of partial discharge may allow appropriate remediative action to be implemented in a timely manner, thereby preventing further degradation and avoiding safety hazards. However, different types of transformers exhibit partial-discharge related signals having a wide range of different characteristics, due to differences in the structures and operating points of the different types of transformers. Moreover, different types of electrical equipment potentially subject to partial defect phenomena, such as cables, breakers, switchgears, control equipment, electric panels, motor starters, variable frequency drives and insulators, exhibit different types of partial discharge-related signals in comparison to one another.

Advantageously, in some embodiments of the present invention, a unified model is created representative of behavior of a wide variety of electrical equipment, notwithstanding structural, operational and other differences that may be present between. The unified model is created based on partial-discharge related signals received from a plurality of electrical devices. The plurality of electrical devices preferably includes a variety of different types of electrical devices which may exhibit partial discharge. For example, the plurality of electrical devices may include a variety of different types of transformers, such as dry and oil transformers, small, medium and large transformers and power generation and distribution transformers.

The unified model of the present invention may be applied to any given electrical equipment or device which may exhibit partial discharge. The application of the unified model to a given electrical device or equipment is preferably irrespective of whether signals from that particular type of electrical equipment were used to create the unified model. For example, the unified model may be applied to signals received from a particular type of transformer despite the unified model having been created based on signals from other types of transformers or based on signals from electrical devices other than transformers, such as other types of high voltage equipment. The creation and application of such a unified model is highly advantageous, since it allows a given electrical device to be monitored for partial discharge without requiring the development of a specific dedicated model for analyzing signals to detect partial discharge from that specific given electrical device.

Turning again to FIG. 1, plurality of electrical devices 102 may include, by way of example only, a first transformer 114, a second transformer 116 and a third transformer 118. It is appreciated that although only three electrical devices are shown in FIG. 1, this is for simplicity of representation only and plurality of electrical devices 102 preferably includes a multiplicity of possibly mutually different types of electrical devices such as a multiplicity of different types of transformers. Electrical devices 102 may be spatially distributed with respect to one another, at different locations.

Preferably, electrical devices monitored by system 100 are stationary and do not include any substantial moving parts. Fault detection based on partial discharge of such stationary electrical equipment, typically operating at high voltages, is particularly complex in comparison to conventional fault detection of mechanical or electrical machines having moving parts, such as motors or generators. This is in part due to the fact that such high-power equipment tends to break down less often than mechanical machine counterparts, such that less data relating to fault development is available. Additionally, the correlation between the signals generated by the electrical device and device malfunction may be unclear, due to the very high energy densities associated with high-power electrical equipment leading to non-linear behavior. It is a particular feature of the system and method of the present invention that the present invention is capable of providing fault detection for such stationary electrical equipment, despite the foregoing detailed challenges, by the provision of a unified model based on and applicable to a wide variety of electrical devices.

Output indications of at least one physical parameter related to electrical discharge may be sensed, by a plurality of sensors 120, from each of plurality of electrical devices 102. Here, by way of example, a first sensor 122 is coupled to first transformer 114, a second sensor 124 is coupled to second transformer 116 and a third sensor 126 is coupled to third transformer 118. Sensors 120 are shown in FIG. 1 to be physically contacting respective transformers 114-118. However, this is not necessarily the case, and sensors sensing physical parameters associated with electrical devices 102 may be contacting or non-contacting. Furthermore, a single sensor may sense physical parameters from more than one device.

One or more sensors may sense one of more physical parameters from one or more of plurality of electrical devices 102. By way of example, sensors 120 may include two or more sensors coupled to one or more of each of electrical devices 102. Sensors 120 may operate continuously or near continuously. Preferably, sensors 120 are installed externally with respect to electrical devices 102 and may be retrofitted to electrical devices 102, such that system 100 may be deployed without requiring special adaptation of transformers thereto. Sensors 120 preferably operate in a non-invasive manner without interfering in the operation of transformers 102 monitored thereby.

Sensors 120 are preferably operative to provide output indications of at least one physical parameter sensed thereby. System 100 preferably includes a signal analyzer 130 operative to receive the output indications from sensors 120 and to generate, at least based thereon, unified model 110 representative of behavior of the plurality of electrical devices 102. Signal analyzer 130 may include a central database. Output indications from sensors 120 may be uploaded to the central database. The central database may be a local database or may be located in the cloud.

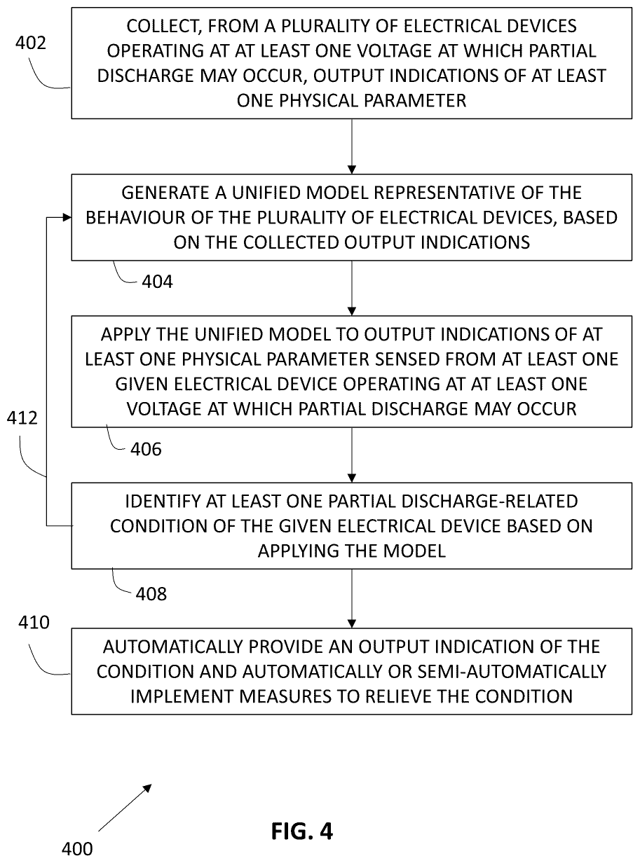

Output indications provided by sensors 120 preferably undergo signal processing either prior to receipt by signal analyzer 130 or by signal processing functionality within signal analyzer 130 in order to extract features therefrom. Signal processing may additionally or alternatively be wholly or partially implemented on the ‘edge’ within ones of sensors 120. The raw output indications provided by sensors 120 and/or features extracted therefrom may be referred to herein as ‘data’ or ‘signals’, interchangeably. Transfer of data from sensors 120 to signal analyzer 130 is indicated generally in FIG. 1 by arrows 140. Further details concerning signal processing techniques that may be employed within the present invention are provided henceforth with reference to FIG. 5A and onwards.

In addition to transfer of data from sensors 120 to signal analyzer 130, signal analyzer 130 may also receive metadata relating to devices 102, such as equipment type, equipment age, equipment rating, process type etc. Such data may collectively be referred to as operational condition data. Data from sensors 120 and optionally the metadata are preferably collected by and accumulated at signal analyzer 130.

Signal analyzer 130 preferably includes computer-implementable algorithms for analyzing the data and optional metadata received thereat, in order to create unified model 110. Unified model 110 may be any type of model representative of the fault-related behavior of plurality of devices 102. Particularly preferably, unified model 110 is a machine-learned model. In accordance with one preferred embodiment of the present invention, unified model 110 may be a Long Short-Term Memory (LSTM) machine learned model capable of providing an indication of partial discharge, although it is appreciated that any suitable unified model 110 may be used within system 100, including, by way of example only, supervised models such as RNN (recurring neural networks), random forest, deep neural networks and transformers or unsupervised models such as K-means or isolation forest algorithms.

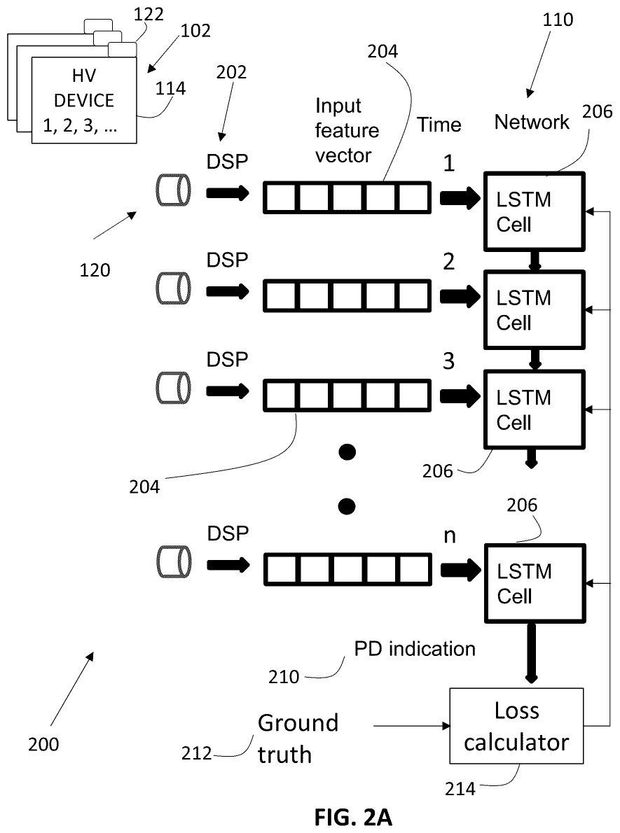

Unified model 110 is preferably initially trained, tested and validated on data collected from sensors 120 during a training period. The generation of model 110 may involve supervised or unsupervised learning. Irrespective of the particular nature and training of model 110, model 110, once trained, tested and validated, preferably constitutes a unified or common model, the parameters of which do not change based on the specific type of electrical device to which the model is applied. Further details relating to how unified LSTM model 110 may be trained on outputs from sensors 120 are provided henceforth with reference to FIG. 2A.

Following the training of unified model 110, system 100 may be operative to apply unified model 110 to the output indications of given electrical device 112 operating at at least one voltage at which electrical discharge, and more particularly partial discharge, may occur. Given electrical device 112 may be a transformer of the same or different type than other ones of transformers 114-118.

In order to apply model 110 to transformer 112, output indications of at least one physical parameter related to electrical discharge may be sensed, by at least one sensor 150, from transformer 112. Here, by way of example, a single physically contacting sensor 150 is shown mounted on transformer 112. However, this is not necessarily the case, and sensors sensing physical parameters associated with transformer 112 may be contacting or non-contacting. Furthermore, a single sensor may sense physical parameters from more than one device and/or two or more sensors may be used to sense two or more physical parameters associated with transformer 112.

At least one sensor 150 may operate continuously or near continuously. Preferably, the at least one sensor 150 is installed externally with respect to electrical device 112 and may be retrofitted to electrical device 112, such that system 100 may be deployed to monitor given transformer 112 without requiring special adaptation of transformer 112 thereto. Sensor 150 preferably operates in a non-invasive manner without interfering in the operation of transformer 112 monitored thereby.

Sensor 150 is preferably operative to provide output indications of at least one physical parameter sensed thereby. Signals provided by sensor 150 preferably undergo signal processing either prior to receipt by signal analyzer 130 or by signal processing functionality within signal analyzer 130, in order to extract features therefrom. Signal processing may additionally or alternatively be wholly or partially implemented on the ‘edge’ within sensor 150. Further details concerning signal processing techniques that may be employed within the present invention are provided henceforth with reference to FIG. 5A and on. The raw output indications provided by sensor 150 and/or features extracted therefrom may be referred to herein as ‘data’ or ‘signals’, interchangeably. Transfer of data from sensors 150 to signal analyzer 130 is indicated generally in FIG. 1 by an arrow 152.

In addition to transfer of data from sensor 150 to signal analyzer 130, signal analyzer 130 may also receive metadata relating to device 112, such as equipment type, equipment age, equipment rating, process type etc. Such metadata may be referred to as operational condition data. Data from sensor 150 and optionally metadata are preferably collected by and accumulated at signal analyzer 130.

Signal analyzer 130 is preferably operative to receive the output indications from sensor 150 and to apply unified model 110 thereto, in order to derive a condition of given device 112, and particularly preferably to provide an output indication of a partial-discharge related condition of given device 112. Further details relating to how unified LSTM model 110 may be applied to outputs from sensor 150 are provided henceforth with reference to FIG. 2B. It is appreciated that unified model 110 may be dynamically updated during operation of system 100, such that data collected from at least one sensor 150 may be added to the data collected by signal analyzer 130 in order to further update and improve the accuracy of unified model 110.

Signal analyzer 130 is preferably operative, by the application of model 110, to identify at least one electrical-discharge related condition of given electrical device 112, the identified condition comprising at least identification of at least one of the presence or absence of electrical discharge and a severity of the electrical discharge if present. Additionally, in the case that electrical discharge is found to be present, system 100 may be operative to provide an indication of the location of the electrical discharge, as is further detailed henceforth.

System 100 preferably includes a human-sensible notification module 160 operative to automatically provide a human sensible output notification including an indication 162 of the at least one identified condition. In some embodiments of the present invention, indication 162 may simply comprise an indication of anomalous behavior of electrical device 112 rather than indication of a specific fault therein. The indication may be provided together with a confidence level showing a confidence associated with the indication.

Notification module 160 may also automatically provide a recommendation 164 of remediation action to relieve the partial discharge if identified. The recommendation 164 may be automatically provided to human experts responsible for managing transformer 112. The recommendation 164 may include a recommendation to alter operating parameters of transformer 112, perform a maintenance or repair action on transformer 112, or in extreme cases, to shut down transformer 112.

The provision of recommendation 164 may lead to an implementation 166 of the recommended remediation action. Implementation 166 may be automatic or implementation 166 may be a human expert implementation. Following performance of implementation 166, the human expert may provide feedback to signal analyzer 130, as indicated by an arrow 170, regarding whether the implementation was successful and ultimately whether the indication 162 and recommendation 164 were found to be accurate. Such feedback may be used by signal analyzer 130 in order to improve the accuracy of unified model 110.

Alternatively, implementation 166 may be automatically performed by a control module of system 100, for example by automatic adjustment of operating parameters of transformer 112 in accordance with recommendation 164.

It is appreciated that although signal analyzer 130 is described herein as a single module, the various collective functionalities of signal analyzer 130 may be split between one or more individual modules, collectively forming signal analyzer 130.

Reference is now made to FIGS. 2A and 2B, which are simplified schematic block diagram illustrations respectively showing training and operation of a model useful within a system of the type shown in FIG. 1.

Turning first to FIG. 2A, a possible training regime 200 for the training of a unified model, such as model 110, is shown, which model 110 may be representative of behavior of a plurality of electrical devices operating at a voltage at which partial discharge may occur, such as devices 102 of FIG. 1, and may be commonly applicable to any given electrical device operating at a voltage at which partial discharge may occur, such as device 112 of FIG. 1.

As seen in FIG. 2A, for each of plurality of electrical devices 102, a time series of output indications of at least one physical parameter sensed by at least one sensor 120 coupled thereto is obtained. Referring to transformer 114 by way of example, a times series of acoustic emission sensed by sensor 122 from transformer 114 may be obtained. The time series may include vibration signals generated by transformer 114 and output by sensor 122 over times 1, 2, 3 . . . n. The vibration signals may undergo digital signal processing (DSP), here indicated by reference number 202, in order to extract features of interest therefrom. At least one feature vector 204 may be derived for each signal in the time series based on the DSP 202. In some embodiments of the present invention, raw signals output by sensor 122 may be provided instead of or in addition to extracted features. The extracted features may be features derived from signal characteristics for each sensor, such as pulse width, pulse amplitude, pulse bandwidth, pulse frequency, pulse statistics and other features. An example of a DSP technique useful for DSP step 202 is provided henceforth with reference to FIGS. 5A and 5B.

The signals, preferably although not necessarily in the form of feature vectors 204, are preferably input into a machine learning model, here embodied, by way of example as an LSTM network, which is a particularly preferred embodiment of unified model 110. It is appreciated, however, that other types of machine learning networks and models are also possible. The LSTM network comprises a plurality of cells 206. Feature vectors 204 corresponding to each time in the time series are preferably input into a corresponding one of cells 206. Here, by way of example, one feature vector 204 is shown to be derived per time in the time series and to be input to a corresponding one cell 206.

The LSTM processes the inputs 204 and outputs an indication of partial discharge 210. The indication of partial discharge may be an indication of the presence or absence of partial discharge and/or indication of the severity of the partial discharge. The indication may alternatively be a simple classification of one or more members of the time series as being anomalous with respect to other members of the times series. For example, the output indication of LSTM 110 may be in the form of a numerical value which is defined as representing an anomaly if the value crosses a predefined or machine learned threshold.

The partial discharge indication 210 is preferably compared to a ground truth 212. Ground truth 212 may be a human expert labelled classification of the same times series as input to the LSTM 110. Ground truth 212 may be compared to partial discharge indication 210 by a loss calculator 214. Loss calculator 214 may compute a loss function representative of the discrepancy between the output indication of LSTM 110 and the corresponding ground truth 212. The loss function may be fed back into cells 206 of LSTM 110 and the parameters of cells 206 updated accordingly, in order to minimize the loss function. This process may be iteratively repeated for each given electrical device 102, over all of electrical devices 102, until the loss function is found to be acceptably small and the parameters of the LSTM 110 sufficiently accurate.

It is appreciated that although the training regime 200 involves supervised learning since a ground truth 212 is provided, unsupervised learning approaches are also contemplated for the training of unified model 110. Furthermore, training regime 200 may also involve the provision of operational parameter data relating to device 114, in order to allow derivation of a correlation between the operational parameter data and sensed data.

Following the training of LSTM 110, the LSTM 110 may be applied to signals from a given electrical device, which given electrical device may or may not have been included in the group of electrical devices 102 used for training in FIG. 2A.

Turning now to FIG. 2B, for a given device N, a time series of output indications of at least one physical parameter sensed by at least one sensor 120 coupled thereto is obtained. Referring to transformer 112 by way of example, a times series of acoustic emission, sensed by sensor 150 from transformer 112, may be obtained. The time series may include vibration signals generated by transformer 112 and output by sensor 150 over times 1, 2, 3 . . . n. The vibration signals may undergo DSP 202, in order to extract features of interest therefrom. At least one feature vector 204 may be derived for each signal in the time series based on the DSP 202. In some embodiments of the present invention, raw signals output by sensor 150 may be provided instead of or in addition to extracted features.

The signals, preferably although not necessarily in the form of feature vectors 204, are preferably input into trained LSTM 110. Each element of the time series 204 is preferably input to a corresponding one of LSTM cells 206. The LSTM processes the inputs 204 and outputs the indication of partial discharge 210. In some cases, the output indication 210 may be fed back into the LSTM 110 in order to further dynamically update the parameters thereof.

It is appreciated that although in FIGS. 2A and 2B, the training of LSTM 110 is shown with respect to a times series of outputs from a single sensor for each electrical device of the plurality of electrical devices, this is a highly simplified representation only. During both training and operation, LSTM 110 may receive, for each electrical device, a multiplicity of output indications of one or more physical parameters related to electrical discharge and sensed from the electrical device, for each element in each time series. The multiplicity of output indications may be provided by a corresponding multiplicity of sensors, which sensors may be operative to sense the same or mutually different physical parameters associated with each electrical device 102 and related to partial discharge.

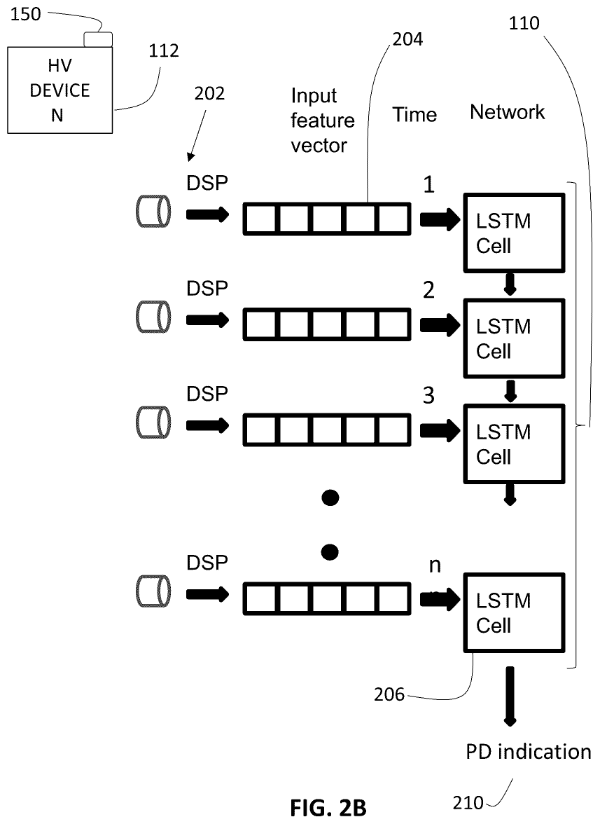

A possible implementation of an LSTM network 300 for processing of a time series containing multiple outputs from multiple sensors is shown in FIG. 3. It is emphasized that the configuration and implementation of the LSTM network 300 shown in FIG. 3 may be incorporated into the unified model 110 of FIGS. 1-2B. However, this is not necessarily the case. In some embodiments of the present invention, the LSTM network 300 of FIG. 3 may be used to process signals from electrical devices subject to partial discharge in order to automatically monitor partial discharge thereof, without being used to create a unified model applicable to other types of electrical devices. In either case, the illustration in FIG. 3 of inputs of multiple signals from multiple sensors is by way of example only, and a fewer or greater number of inputs signals are also within the scope of the present invention.

As seen in FIG. 3, there is provided a time series 304 of output indications of at least one physical parameter sensed from an electrical device operating at at least one voltage at which partial discharge may occur. Each element of the time series includes signals sensed by a plurality of sensors 320 coupled to the given electrical device. Here, by way of example, the time series is seen to comprise signals sensed by three sensors, over times 1, 2, 3 . . . n. The signals may be, but are not necessarily, mutually different, for example an acoustic emission signal, magnetic field or flux signal, RF signal and temperature signal. In a particularly preferred embodiment of the present invention, at least a vibration sensor and magnetic flux sensor are included in plurality of sensors 320.

An example of a vibration sensor suited for use in the present invention for measuring acoustic emission signals related to partial discharge of transformers is a piezoelectric acoustic emission sensor, such as the VS900-M with a pre-amplifier available from Vallen Systeme of Germany. An example of a magnetic sensor suited for use in the present invention for measuring magnetic fields related to partial discharge of transformers is a Hall effect sensor such as the SS495A1 available from Honeywell of the USA. Particularly preferably, the sensors are externally located with respect to the monitored device. For example, the vibration sensor and magnetic sensor may be mounted on an external wall of the monitored device.

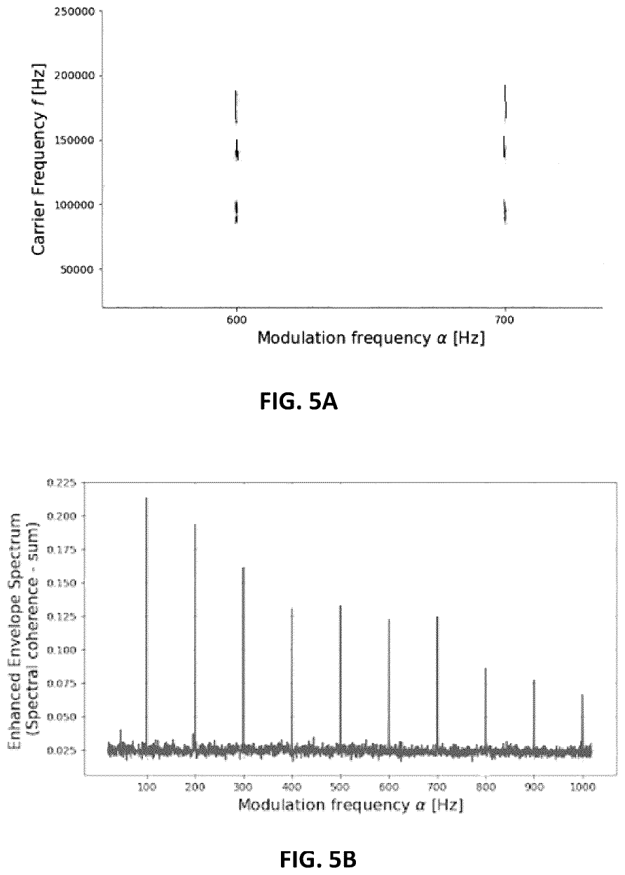

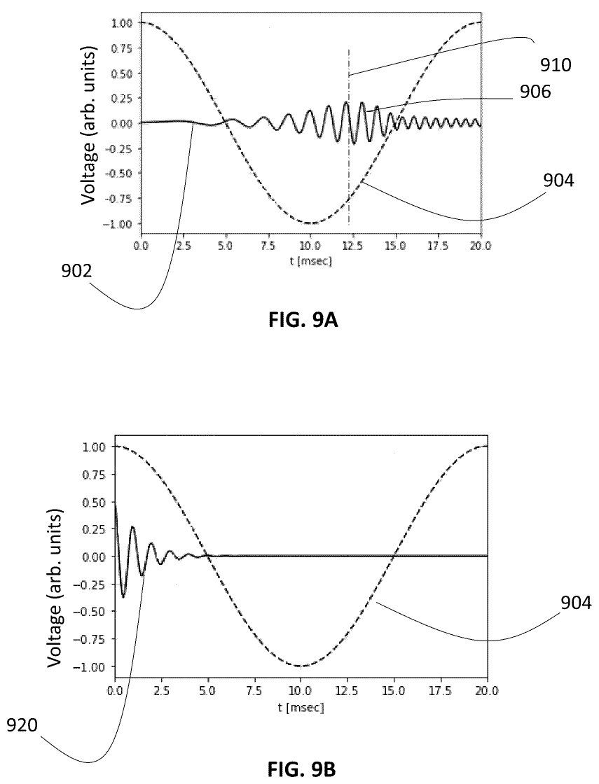

The sensed signals may undergo digital signal processing (DSP), here indicated by reference number 322, in order to extract features of interest therefrom. The extracted features may be features derived from signal characteristics for each sensor, such as pulse width, pulse amplitude, pulse bandwidth, pulse frequency, pulse statistics and other features. An example of a DSP technique for processing signals input to LSTM 300 is provided henceforth with reference to FIGS. 5A-5B. Due to the input of signals from multiple sensors, the extracted features may additionally or alternatively be inter-sensor features, examples of which is provided henceforth with reference to FIGS. 6A and 6B and 9A and 9B. At least one feature vector 324 may be derived for each signal in the time series based on the DSP 322. In some embodiments of the present invention, raw signals output by sensors 320 may be provided instead of or in addition to extracted features.

The signals, preferably although not necessarily in the form of feature vectors 324, are preferably input into LSTM network 300. The LSTM network comprises a plurality of cells 326. Each element of the time series 304 is preferably input to a corresponding one of cells 326. The LSTM processes the inputs 304 and outputs an indication of partial discharge 330. The indication 330 of partial discharge may be an indication of the presence or absence of partial discharge, location of partial discharge and/or indication of the severity of the partial discharge. The indication may alternatively be a simple classification of one or more members of the time series being anomalous with respect to other times series. For example, the output indication 330 of LSTM 300 may be in the form of a numerical value which is indicative of an anomaly if the value crosses a threshold.

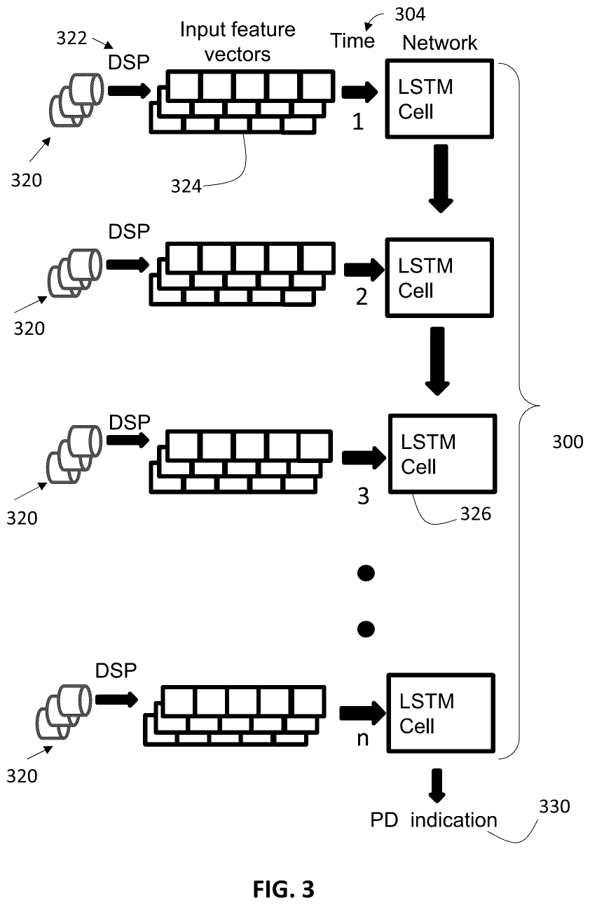

Reference is now made to FIG. 4, which is a simplified flow chart illustrating steps in a method for monitoring of electrical devices, as may be carried out by a system of the type shown in FIG. 1.

As seen in FIG. 4, a method for monitoring electrical devices for partial discharge 400 may begin at a first step 402 by collecting, from a plurality of electrical devices operating at at least one voltage at which partial discharge may occur, output indications of at least one partial-discharge related physical parameter. By way of example, the partial-discharge related physical parameter may be sensed by a plurality of sensors corresponding to the plurality of electrical devices, such as sensors 120 of FIG. 1. Plurality of electrical devices may be high-voltage devices such as high-power transformers. Plurality of electrical devices may include different types of the same device, such as different types of transformers, and/or different types of electrical devices, such as electrical cables, breakers, switchgears, control equipment, electric panels, motor starters, variable frequency drives, insulators etc.

As seen at a second step 404, a unified model may be generated based on the collected output indications. The unified model is preferably representative of fault-related behavior of the plurality of electrical devices from which output indications were obtained at first step 402, notwithstanding differences which may exist therebetween.

As seen at a third step 406, the unified model may be applied to output indications of the at least one physical parameter sensed from at least one given electrical device operating at at least one voltage at which partial discharge may occur.

As seen at a fourth step 408, at least one partial discharge related condition of the given electrical device may be identified based on applying of the model. The identified condition may include detection of the presence or absence of partial discharge and the severity of partial discharge if identified to be present. Additionally, the location of the partial discharge, if identified to be present, may be identified.

As seen at a fifth step 410, an output indication of the identified condition may be automatically provided, for example to a human expert. Additionally, in some cases, the method may include automatically or semi-automatically, for example subject to human approval, implementing measures to relieve the partial-discharge related condition.

In some embodiments of the present invention, the device condition derived at fourth step 408 may be fed back to second step 404, as indicated by an arrow 412, and second step 404 may be repeated based on now taking into account the new data, in order to dynamically update and improve the model. Second step 404 may be continuously repeated during method 400 as new data becomes available.

Reference is now made to FIGS. 5A and 5B, which are respective graphs illustrating cyclostationary signal processing, which may be useful in conjunction with the system of FIG. 1, the models of FIGS. 2A-3 and the method of FIG. 4, although not limited to use therein.

FIGS. 5A and 5B illustrate outputs of cyclostationary signal processing of acoustic signals generated by a transformer and indicative of partial discharge. Cyclostationary signal processing techniques such as those described hereinbelow with reference to FIGS. 5A and 5B may be applied to signals sensed from electrical devices in order to derive features thereof. The derived features may be used as a basis for signal analysis, in order to identify partial discharge. By way of example, cyclostationary signal analysis may be performed as part of the DSP step in order to extract features that are input into unified model 110 (FIG. 1) or model 300 (FIG. 3). The cyclostationary signal analysis may also be advantageously employed as a ‘stand alone’ technique for signal processing of partial-discharge related signals, for improving signal to noise ratio and/or improving accuracy of localization of partial discharge, as well as other advantages as will be apparent from the following description.

It is appreciated that the following description relates to analysis of acoustic emission from transformers as an example of one preferred embodiment of the present invention only and may be applied to analysis of other types of signals from other types of electrical devices operating at voltages at which partial discharge may occur, such as high voltage devices.

Acoustic emission signals indicative of partial discharge are typically in the form of pulses. It has been realized by the inventors of the present invention that partial discharge may be considered to be a cyclostationary phenomenon generating a signal having statistical properties varying cyclically with time and as such, that cyclostationary signal processing techniques may be particularly well suited for processing of acoustic emission pulses generated by partial discharge events. An exemplary cyclostationary signal processing technique is now described with respect to processing of partial-discharge related acoustic emission pulses. However, it is appreciated that other cyclostationary signal processing techniques may also be implemented.

The waveform of partial-discharge related acoustic pulses may be characterized by two parameters: the time separation T in seconds between the pulses, which is the inverse of the pulse rate a per second, and the frequency f of the pulse itself. The pulse rate a in Hz may be termed the modulation frequency and the pulse frequency f in Hz may be termed the carrier frequency. The cyclic spectral coherence of the acoustic emission pulses may be found by decomposing the pulses into the modulation and carrier frequencies. A simplified graph showing cyclic spectral coherence of the carrier frequency with respect to the modulation frequency is shown in FIG. 5A.

In order to find the cyclic spectral coherence, as shown for example in FIG. 5A, the only a priori signal property that is required is the pulse rate a. This is readily known, since it may be assumed that electrical discharge occurs once or twice within each electric cycle. For example, partial discharge typically occurs twice within each electric cycle and electrical corona once within each electrical cycle. For a grid frequency of 50 Hz, electrical discharge thus occurs 50 or 100 times per second and a is equal to 50 or 100 Hz. Cyclic spectral coherence would therefore be expected to be seen at harmonics or multiples of 50 or 100 Hz. By way of example, in FIG. 5A, cyclic spectral coherence is seen at 600 Hz and 700 Hz. It is appreciated that in FIG. 5A only a portion of the spectrum is shown and other harmonics would be expected to be seen at other multiples of 100 Hz.

It is a particular advantage of this technique that prior knowledge of only a single well defined signal property is required. This is in contrast to other conventional partial-discharge related acoustic analysis techniques which require knowledge or estimation of other signal parameters which are typically difficult or impossible to accurately ascertain and may vary between devices and within devices depending on the particular operating conditions thereof. Furthermore, the application of such cyclostationary analysis serves to improve the signal to noise ratio of the acoustic emission. As a result of these and other features, the accuracy with which partial discharge may be detected is improved.

An enhanced envelope spectrum in which the summed spectral coherence is plotted against the modulation frequency a is shown in FIG. 5B. A wide variety of features may be extracted from the cyclic spectral coherence, as illustrated in FIG. 5A, and enhanced envelope spectrum, as illustrated in FIG. 5B, in order to facilitate distinguishing between acoustic emission pulses indicative of partial discharge and acoustic emission pulses not indicative of partial discharge. By way of example only, the standardized Euclidean distance (SED) between the 100 Hz harmonics in the enhanced envelope spectrum and the background may be calculated. The deviation of the harmonics' location from multiples of 100 Hz may also be considered. Taking the example shown in FIG. 5B, in this case the enhanced envelope spectrum is considered to be indicative of partial discharge being present due to the shape thereof.

In some embodiments of the present invention, features extracted using cyclostationary signal analysis may be input as feature vectors to a machine learned model in order to detect partial discharge, such as model 110 and 300 of FIGS. 1-3. In other embodiments of the present invention, features extracted using cyclostationary signal analysis may be treated using mathematical or other models in order to detect partial discharge.

A variety of other DSP techniques may also be included in the scope of the present invention, as may be known in the art, including Short Time Fourier Transfer analysis (STFT), discrete wavelet transforms (DWT), spectrograms and others. In addition, the DSP may involve manipulating the signal for the purpose of downsampling and decimating the signal. The DSP may also involve signal filtering. In accordance with one particularly preferred embodiment of the present invention, the signal may be filtered in different spectral bands. The band for which the Crest factor, defined as the ratio between the signal peak and the signal's RMS, is highest is then found. That band is then sliced into successively narrower bands over which the process is repeated, until narrowest spectral band having the highest Crest factor is found. Finally, the envelope of the signal may be found and noise that does not cross a threshold value set to zero, which results in a train of pulses that were emitted from a discharge event and may be provided for further processing downstream.

Still other signal features may be useful for evaluating degradation of the monitored device, as a result of increasing severity of partial discharge events therein, over time. An example of signal analysis techniques useful for evaluating degradation over time is now described with reference to FIGS. 6A-6C.

Reference is now made to FIGS. 6A-6C, which are respective graphs showing relative trends in signals over time, useful in conjunction with the system and method of any of FIGS. 1-4 although not limited thereto.

As described hereinabove, multiple physical parameters may be sensed from electrical devices operating at voltages at which partial discharge may occur, in order to monitor whether or not these devices are exhibiting partial discharge and if so, to evaluate the severity of the partial discharge.

In one preferred embodiment of the present invention, trends in the development of partial discharge over time may be evaluated based on a comparison over time of magnetic signals sensed from at least one electrical device, such as a transformer, and acoustic emission pulses sensed therefrom.

The magnetic flux signal generated by a transformer tends to include many frequencies, which frequencies may be extracted by performing a Fourier transform on the magnetic flux spectrum. The dominant frequency of the frequency spectrum typically corresponds to the magnetic line frequency, which is the frequency of fluctuation of the magnetic field and corresponds to the frequency of fluctuation of voltage in the transformer, which voltage fluctuation is responsible for generating the magnetic field.

The severity of partial discharge in a transformer may be evaluated based on the phase of the transformer voltage at which an acoustic pulse indicative of partial discharge is generated. The lower the voltage in the transformer giving rise to an acoustic pulse indicating partial discharge, the more severe the partial discharge is considered to be, since the partial discharge is induced at a lower voltage. Conversely, the higher the voltage in the transformer at which partial discharge occurs, as indicated by an acoustic pulse, the less severe the partial discharge is considered to be, since the partial discharge is only induced at a higher voltage. Based on the understanding that the variation of the magnetic flux signal at the magnetic line frequency is representative of the voltage variation in the transformer, the acoustic pulse sensed from a transformer may therefore be considered relative to the phase of the magnetic flux signal at which the acoustic pulse occurs in order to evaluate progression of partial discharge over time.

As seen in FIGS. 6A and 6B, an acoustic signal 602 sensed from a transformer comprises a series of acoustic pulses 604. In this case, each acoustic pulse is considered to be indicative of a partial discharge event. Also shown in FIGS. 6A and 6B is a magnetic flux signal 606 filtered around the magnetic line frequency. The amplitudes of both the acoustic signal and magnetic flux signal are displayed in volts, in arbitrary units (arb. unit). As seen in FIG. 6A, during a first time period T1 acoustic pulses 604 are located with respect to the phase of the magnetic flux signal at a voltage of approximately ±0.75 arb. units, as demarked by dashed lines 610. As seen in FIG. 6B, during a second time period T2 acoustic pulses 604 are seen to have shifted with respect to the magnetic flux signal 606 and to be newly located with respect to the phase of the magnetic flux signal at a voltage of approximately ±0.5 arb. units, as demarked by dashed lines 612. The voltage required to excite a partial discharge event during time period T2 is seen to be lower than the voltage required to excite a partial discharge event during time period T1. The severity of the partial discharge fault is therefore understood to be increasing over time from period T1 to period T2.

As depicted in a highly schematic generalized form in FIG. 6C, the greater the time shift between the phases of the magnetic and vibration signals, in the direction of decreasing voltage of magnetic signal with respect to vibration signal, the more severe the degradation of the transformer. The curve of FIG. 6C represents degradation over time of the transformer, based on the trend seen in the increasing time shift between the phases of the magnetic and vibration signals. It is understood that the time shift refers to the shift in time between the acoustic pulse and a maximum or minimum of the magnetic flux signal 606.

It is understood that, due to the differences in speed of propagation of the magnetic signal and the vibration signal, the phase and corresponding voltage at which the acoustic pulse is seen to occur with respect to the magnetic signal does not represent the true or absolute point in time at which the acoustic signal occurs with respect to the phase of the magnetic flux signal. This is because the acoustic signal travels at a much slower speed than the magnetic signal from the source of the partial discharge towards the sensor by which it is sensed, such that the time at which the acoustic signal is sensed is in fact later than the time of generation thereof. In contrast, since the magnetic field signal travels at a speed which is close to the speed of light, the magnetic signal may be indeed considered to be sensed effectively instantaneously with the generation thereof. As a result, an apparently simultaneous magnetic and vibration signal, sensed at the same time, did not actually occur at the same time.

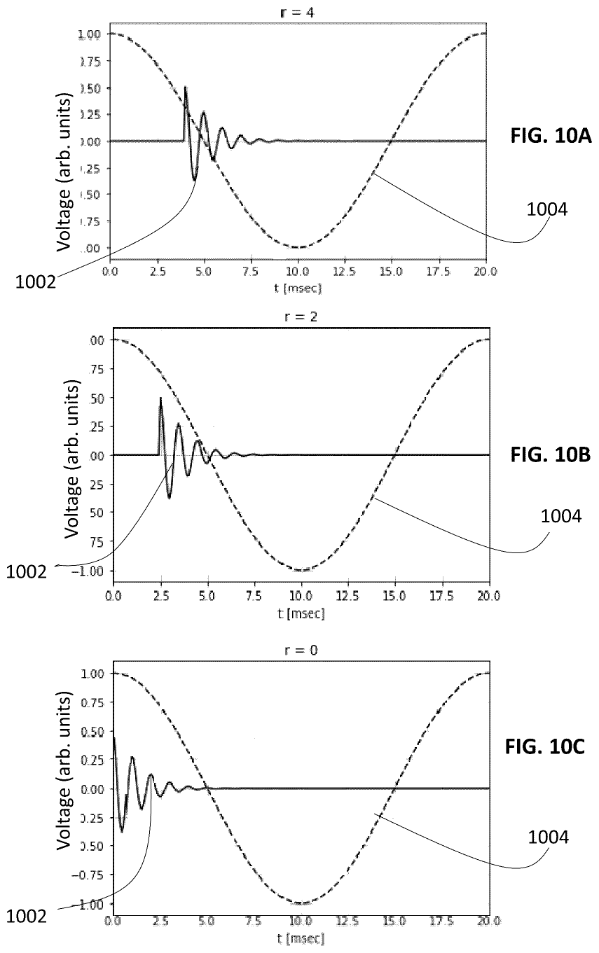

Due to the difference in time scales between the propagation and hence sensing of the magnetic and vibration signals, the relative shift between the signals may be used as an indicator of trends in the shift in time/phase therebetween and hence progression over time of partial discharge, but cannot serve as an accurate indicator of the absolute voltage at which the partial discharge occurs. Further details are provided henceforth, with reference to FIGS. 9A-10C, regarding absolute comparison of magnetic and vibration signals along a common time scale, in accordance with other preferred embodiments of the present invention.

It is appreciated that the trend in shift in time between the magnetic and vibration signal may be analyzed as part of the DSP step of FIGS. 1-3 in order to extract features that may be input into unified model 110 (FIG. 1) or model 300 (FIG. 3). The trend in shift in time between the magnetic and vibration signal may also be advantageously employed as a ‘stand alone’ technique for signal processing of partial-discharge related signals, in order to evaluate progression in severity of the partial discharge signal over time.

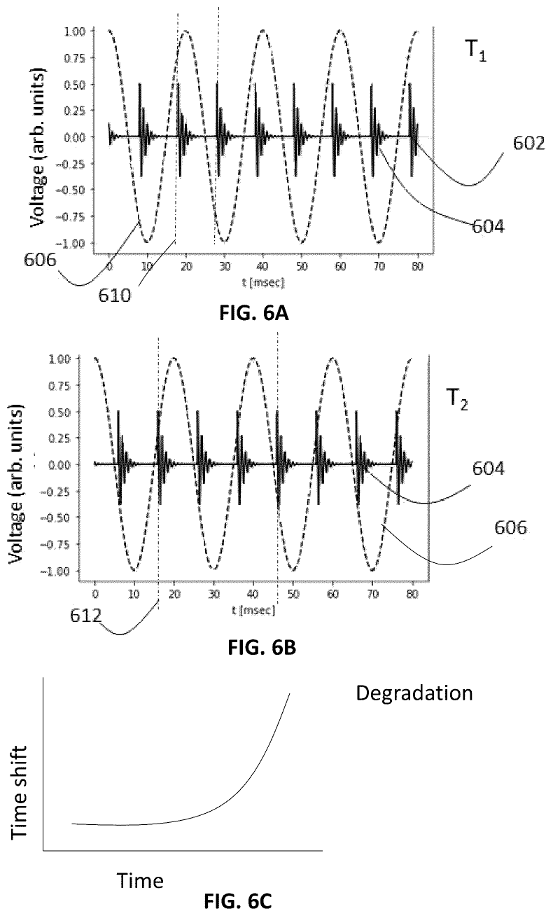

Reference is now made to FIG. 7, which is a simplified schematic block diagram illustration of a system for monitoring of electrical devices, constructed and operative in accordance with another preferred embodiment of the present invention.

As seen in FIG. 7, there is provided a system 700 for monitoring a condition of an electrical device 702 operating at a voltage at which partial discharge may occur. Electrical device 702 may be any type of electrical device or equipment operating at voltages and/or apparent powers at which electrical discharge phenomena may occur. Such electrical equipment may be high voltage electrical equipment. By way of example only, system 700 may be used for condition monitoring of high voltage electrical equipment operating at voltages of at least one kilovolt or at least one MVA. By way of example, such high voltage electrical equipment may operate at voltages in the range of 1-1000 kilovolts and/or at powers of 1-1000 MVA. However, it is understood that electrical discharge and more particularly partial discharge may also be exhibited by electrical equipment operating at lower voltages and/or apparent powers and such electrical equipment is also included in the scope of equipment to which system 700 may be applicable. For example, electrical device 702 may be embodied as a high-power transformer, electrical cable, breaker, switchgear, control equipment, electric panel, motor starter, variable frequency drive, insulator etc. In the following description, electrical device 702 will be referred to as a transformer and electrical discharge due to faults therein as partial discharge, although it is appreciated that this is simply one preferred implementation of the present invention.

During operation of transformer 702, transformer 702 may develop faults leading to generation of partial discharge, indicated schematically by reference number 704 in FIG. 7. At least one physical parameter associated with transformer 702 and related to partial discharge may be sensed by at least one sensor coupled to transformer 702. Here, by way of example, a first sensor 710 and a second sensor 712 are shown to be coupled to transformer 702, although more sensors on a single device and fewer or more sensors on more than one transformer are also possible. Sensors 710 and 712 may or may not physically contact transformer 702. Sensors 710 and 712 may be operative to provide output indications of the same physical parameter associated with transformer 702. For example, sensors 710 and 712 may both be vibration sensors operative to sense signals acoustic emission from transformer 702. Additionally or alternatively, sensors 710 and 712 may be operative to provide output indications of mutually different respective physical parameters associated with transformer 702. For example, sensor 710 may be a vibration sensor and sensor 712 may be a magnetic field sensor.

An example of a vibration sensor suited for use in the present invention for measuring acoustic emission signals related to partial discharge of transformers is a piezoelectric acoustic emission sensor, such as the VS900-M with a pre-amplifier available from Vallen Systeme of Germany. An example of a magnetic sensor suited for use in the present invention for measuring magnetic fields related to partial discharge of transformers is a Hall effect sensor such as the SS495A1 available from Honeywell of the USA. Particularly preferably, the sensors are externally located with respect to the monitored device. For example, the vibration sensor and magnetic sensor may be mounted on an external wall of the monitored device.

Output indications of the at least one physical parameter, for example sensed by sensors 710 and 712, may be provided thereby to signal transformation functionality 720. Signals may be pre-processed with signal processing techniques prior to provision thereof to signal transformation functionality 720. For example, any suitable signal processing techniques as may be known in the art, as well as any one or more of the signal processing techniques described hereinabove with reference to FIGS. 1-6C, may be applied to signals from sensors 710 and 712.

Signal transformation functionality 720 is preferably computer implemented functionality, operative to perform a transformation on at least one of the first and second signals received thereat so as to generate at least one transformed signal having at least one characteristic in common with the other one of the at least first and second signals. The transformation performed by signal transformation functionality 720 may be backpropagation, forward propagation or dispersion correction, as will be explained in greater detail henceforth. In one preferred embodiment of the present invention, by way of the transformation at least one characteristic of the signal may be transformed so as to correspond to a characteristic of that signal as originally generated at a source thereof. The transformation thus may serve to substantially restore one or more characteristics of the original signal based on the measured signal.

In sensing of signals generated by or associated with partial discharge, such as acoustic emission pulses, the signals tend to evolve and degrade as they propagate from the fault location or source at which the signals are generated to the sensor at which the signals are sensed. In the case of acoustic emission pulses, by way of example, the pulses tend to accumulate phase and thus broaden and attenuate as the pulses travel through various media that may be present between the fault location and the sensor. In addition, there is a time delay between the time at which the signal is generated and the time at which the signal is sensed, due to the time taken for the signal to travel from the source thereof to the sensor.

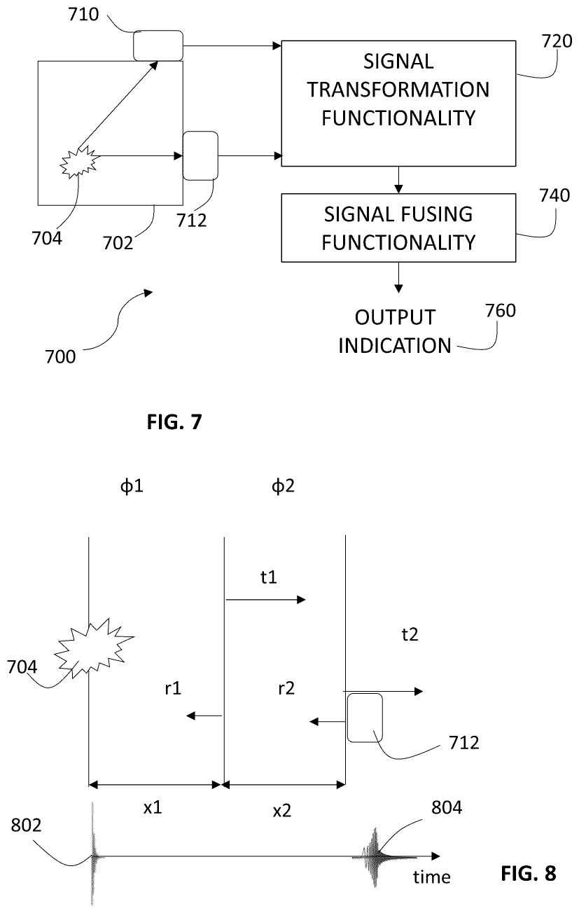

A highly simplified schematic representation of propagation of a signal arising from partial discharge event 704, as the signal travels towards sensor 712 whereat the signal is sensed, is shown in FIG. 8. As seen in FIG. 8, an acoustic pulse, schematically represented as an acoustic pulse 802, is generated as a result of partial discharge 704. The acoustic signal may propagate through a first medium having a first width x₁ over which first medium the signal accumulates a first phase Φ₁ followed by a second medium having second width x₂ over which second medium the signal accumulates a second phase Φ₂. The transmission and reflection coefficients of the first and second media are indicated as t₁, r₁ and t₂, r₂ respectively and further influence the characteristics of the signal as output by sensor 712. Acoustic pulse 802, as sensed by sensor 712, is schematically shown as a sensed acoustic pulse 804. Sensed acoustic pulse 804 is broadened, attenuated and time delayed in comparison to original acoustic pulse 802. However, by backpropagating sensed acoustic pulse 804, these degrading effects may be substantially corrected for and an approximation of the original acoustic pulse 802, at its original time of propagation and substantially in its original waveform, may be retrieved.

The transformation applied to the measured signal may involve phase compensation in order to derive a signal approximating the original signal as generated. The phase compensation may be performed by backpropagation of the at least one measured signal over a known distance to a source of the signal, in the case that the fault location is known. By way of example, in the case that at least four sensors are used to monitor a given device, triangulation methods may be used based on signals from the multiple sensors in order to locate the source of the signals and thus find the distance of each sensor from the source.

Taking an acoustic wave as an example, the propagation of the wave in a medium may be derived from the Navier-Stokes equations and expressed as:

$$\frac{1}{{ρ}_{0} {c}^{2}} \frac{{\partial }^{2} P}{\partial {t}^{2}} - \frac{1}{{ρ}_{0}} {Δ}^{2} P = S ( t ) δ ( \hat{r} - \hat{{r}_{0}} ) \qquad ( 1 )$$

where P is the pressure of the acoustic wave, t is time, ρ₀ is the medium density, c is the acoustic wave velocity which is dependent on the wave frequency, r₀ is the partial discharge source position, r is the position to which the wave propagates, δ is the Dirac function and S is a point source of energy flow representing the energy emitted locally from the partial discharge event. Beyond the discharge position r₀ which acts as a boundary condition the acoustic waves may propagate freely through the medium.

The dispersion relation k of these acoustic waves as they propagate through the medium may be expressed as:

$$k = \frac{ω}{c ( ω )} \approx \frac{{ω}_{0}}{c {ω}_{0}} + \frac{d}{d ω} \frac{ω}{c ( ω )} {\vert}_{{ω}_{0}} ( ω - {ω}_{0} ) + \frac{1}{2} \frac{{d}^{2}}{d {ω}^{2}} \frac{ω}{c ( ω )} {\vert}_{{ω}_{0}} {( ω - {ω}_{0} )}^{2} \qquad ( 2 )$$

In equation (2) ω is the angular frequency of the acoustic wave and ω₀ is the central angular frequency within the acoustic emission spectrum representing the discharge event and typically lies in the 100 kHz-200 kHz range, as this frequency range characterizes the acoustic signals emitted by partial discharges. The second term in equation (2) is proportional to the inverse of the wave group velocity which expresses the velocity at which the pulse travels through the medium and hence the time delay in the signal between source and sensor and the third term represents the group velocity dispersion.

The relationship expressed in equation (2) is general and represents both dispersion and attenuation effects. Henceforth in this analysis, for the sake of simplicity, the effect of dispersion only is considered, although it is appreciated that other relevant effects as expressed in equations (1) and (2) may be taken into account.

For partial discharge, the energy source S may be described as a multiplication of a sigmoid function representing the rise time, an exponential function representing the decay and an oscillating part that represents the wave oscillations as follows:

$$S = \frac{1}{1 + {e}^{- at}} {e}^{- bt} cos ( 2 π ft ) \qquad ( 3 )$$

where a controls the pulse ramp-up, b is the decay rate and f is the frequency of the acoustic wave.
Combining equations (1)-(3) yields:

$$- \frac{{ω}^{2}}{{ρ}_{0} {c}^{2}} P ( ω ) + \frac{1}{{ρ}_{0}} {k}^{2} P ( ω ) = S ( ω ) \qquad ( 4 )$$

and consequently

$$P ( ω ) = \frac{{ρ}_{0} S ( ω )}{{k}^{2} - \frac{{ω}^{2}}{c}} \qquad ( 5 )$$

such that

$$P ( t ) = {ρ}_{0} Re \{ \int S ( ω ) {e}^{- i ω t - i \frac{ω}{c} r} d ω \} \qquad ( 6 )$$

Equation (6) shows that the pressure wave P after propagating distance r accumulates a phase of (ω/c)×r. It is understood that equation 6 represents the waveform of the acoustic pulse as measured at the sensor. In the case that the dispersion of the medium is known, the accumulated phase and time delay may be evaluated using equation (2) in combination with equation (6). In order to backpropagate the wave and correct for the accumulated phase, the integral in equation (6) is multiplied by an additional exponent e^{iωr/c}, which serves to cancel out the phase accumulated over distance r. In other words, the frequency domain representation of the pulse at the sensor is multiplied by e^{iωr/c} in order to derive the backpropagated, phase corrected waveform.

Backpropagating the pulse by correcting the measured pulse for accumulated phase, based on equation (6), yields a pulse having phase characteristics and thus the waveform of the pulse as generated at the source thereof. In the case that attenuation is also taken into account in equations (3)-(6), backpropagation of the pulse based on equation (6) yields as pulse having both the amplitude and phase characteristics of the pulse as generated at the source thereof.

The backpropagation calculation of equations (1)-(6) may be performed for any type of medium, including oil, copper waveguiding wires, steel, etc. In more complex media, equations (1)-(6) may be modified to take into account the phase accumulation through multiple media. It is appreciated that the backpropagation of the present invention is not limited to being calculated via equations (1)-(6) and other approaches to finding the backpropagated wave or other approaches to phase compensation may also be employed.

It is appreciated that, in some cases, the distance to the partial discharge event may be unknown. For example, transformer 702 may be monitored by only two sensors, as shown in FIG. 7, such that triangulation of signals to find the location of the source of the emission is not possible. Alternatively, multiple sensors may be present but it may nonetheless be advantageous to avoid the need to calculate the distance to the source.

In accordance with a preferred embodiment of the present invention, signals indicative of partial discharge, such as acoustic emission signals, rather than being backpropagated over a known predetermined distance, may rather be backpropagated until the signal becomes transform limited, meaning that the signal becomes as narrow as possible in the time domain. The transform limited signal may be considered to correspond to the signal as originally generated at the location of the partial discharge event within transformer 702. The distance over which the signal is backpropagated in order to arrive at the transform limited pulse is considered to be the distance from the sensor to the source location.

In order to find the transform limited signal, the backpropagated signal waveform may be found for different values of r, where r is the distance of the sensor from the source, based on equation (6). For each r, the width of the pulse may be found, for example the pulse FWHM or the width of the pulse that contains a certain percentage of the pulse energy. The value of r yielding the lowest width for the waveform is then found. This lowest width waveform is considered to be the transform limited waveform and the value r at which this lowest width waveform is found is considered to be the distance of the sensor from the source.

This technique allows the distance to the signal source to be found without any a priori knowledge of the source location or the use of multiple sensors for triangulation. Furthermore, this technique allows restoration of an approximation of the original signal at its source, regardless of the type of device being monitored or the medium through which the signal propagates to reach the sensor.

It is noted that in cases where the wave may propagate through more than one medium en route to the sensor, the backpropagation may be based on standard transfer matrix methods that consider the phase accumulated in each component, and the complex reflection and transmission amplitudes accumulated at interfaces, as illustrated in FIG. 8.

The use of backpropagation to restore original signal characteristics of signals representative of partial discharge may have several highly advantageous applications useful in various embodiments of the present invention, including in evaluation of fault severity, in improving the accuracy of fault localization and in increasing commonality between fault signals generated by diverse devices thereby allowing such signals to be used as a basis for developing a unified model such as model 110 of FIG. 1, as is further detailed henceforth.

The at least first and second signals, at least one of which is now transformed, may be provided to signal fusing functionality 740. Signal fusing functionality 740 is preferably operative to fuse the at least first and second signals, at least one of which is transformed. For example, the signal fusing functionality may be operative to align the at least first and second signals on a common timeline or to combine the at least first and second signals as inputs to a machine learning model, such as unified model 110 of FIGS. 1-2B. Based on the fusing, a partial-discharge related condition of the at least one electrical device 702 may be derived and provided in the form of a human sensible output 760.

In one particularly preferred embodiment of the present invention, backpropagation of acoustic emission signals in order to restore the signals' source characteristics may allow a more accurate, absolute, comparison of vibration signals to magnetic flux signals measured from the same device over a corresponding time period. This may be used as a basis to evaluate severity of partial discharge.

The use of backpropagation to aid fusing of magnetic flux signals with vibration signals in the form of acoustic pulses indicative of partial discharge events may be better understood with reference to FIGS. 9A and 9B.

Reference is now made to FIGS. 9A and 9B, which are simplified respective graphs illustrating fusing of signals indicative of electrical discharge in electrical devices, in accordance with one preferred embodiment of the present invention.

Turning first to FIG. 9A, an acoustic emission signal 902 is plotted on a common axis with respect to a magnetic flux signal 904. Both the acoustic emission signal 902 and the magnetic flux signal 904 are preferably obtained from and generated by the same electrical device, such as transformer 702. FIG. 9A is representative of the two signals as sensed. As can be seen, the two signals 902 and 904 are measured over a common 20 millisecond time period. The amplitudes of both the acoustic signal 902 and magnetic flux signal 904 are displayed as volts in arbitrary units (arb. units). The magnetic flux signal may be considered to be representative of the transformer voltage, calculated from the magnetic line frequency of the magnetic flux signal.

The acoustic emission signal 902 is seen to include a broad pulse 906 indicative of partial discharge. As explained hereinabove with reference to FIGS. 6A-6C, the severity of partial discharge in a transformer may be evaluated based on the phase of the transformer voltage at which an acoustic pulse indicative of partial discharge is generated. The lower the voltage in the transformer giving rise to an acoustic pulse indicating partial discharge, the more severe the partial discharge is considered to be, since the partial discharge is induced at a lower voltage. Conversely, the higher the voltage in the transformer at which partial discharge occurs, as indicated by an acoustic pulse, the less severe the partial discharge is considered to be, since the partial discharge is only induced at a higher voltage. Based on the understanding that the variation of the magnetic flux signal at the magnetic line frequency is representative of the voltage variation in the transformer, the acoustic pulse sensed from a transformer may therefore be compared to the phase of the magnetic flux signal in order to evaluate severity of the partial discharge.

In FIG. 9A, pulse 906 is seen to occur at time t=12.5 ms and to correspond in time to an intermediate voltage as represented by the magnetic flux signal of −0.75 arbitrary units. The occurrence of pulse 906 with respect to the phase of the voltage is demarked in FIG. 9A by a dashed line 910. From consideration of the phase of the voltage at which the acoustic pulse occurs, based on FIG. 9A, it would appear that the partial discharge is of intermediate severity, since the voltage level at which the partial discharge effect is created is intermediate. However, as explained hereinabove, due to the time taken by the acoustic signal 906 to propagate within transformer 702 and reach sensor 712, the time at which the acoustic signal is sensed is later than the actual time at which the acoustic signal was generated by a partial discharge event. In contrast, due to the speed of propagation of the magnetic flux signal, the time at which the magnetic flux signal is sensed may be considered to be effectively instantaneous with respect to the time at which the signal was generated. As a result, the display of the two signals as sensed on a common timeline, as is shown in FIG. 9A, is not truly representative of the temporal relationship therebetween and insights regarding the apparent severity of the partial discharge derived therefrom may be incorrect.

In order to overcome this limitation, acoustic signal 906 may be backpropagated to correct the acoustic signal for phase accumulated during propagation of the signal, thus narrowing and sharpening the signal and allowing more accurate identification of the time at which the signal peak occurs. The transform limited back propagated signal may be considered to correspond to the waveform of the signal as originally generated, with zero distance and time delay from the source. Acoustic signal 906 may be backpropagated over a known distance to the source thereof, as described hereinabove with respect to equations (1)-(6). Alternatively, acoustic signal 906 may be backpropagated until the signal becomes transform limited, as described hereinabove.

Turning now to FIG. 9B, magnetic signal 904 representing transformer voltage is again plotted against a backpropagated version of vibration signal 902, here indicated by reference number 920. As appreciated from consideration of FIG. 9B in comparison to FIG. 9A, pulse 906 is seen to narrow and sharpen due to removal of phase errors accumulated during propagation thereof and corrected for by backpropagation. Furthermore, pulse 906 is seen to move backwards along the time axis to occur at time t=0, representing the time at which the acoustic pulse was generated in the transformer as result of partial discharge. It is appreciated that in FIG. 9B the magnetic signal 904 and vibration pulse 920 are now accurately displayed along a common timeline, since the apparent time at which the vibration signal occurs has been corrected for the time delay due to the relatively slow propagation thereof. FIG. 9B thus presents an accurate snapshot in time of acoustic emission pulse 906 with respect to the phase of the transformer voltage, represented by the magnetic signal 904.

The time at which the pulse 906 occurs with respect to the phase of the voltage is along the y-axis, at time t=0. As appreciated from consideration of FIG. 9B, the acoustic pulse 906 occurs at a peak of the magnetic signal corresponding to a maximum voltage. The partial discharge giving rise to pulse 906 is therefore understood to be of low severity. It is appreciated that the accuracy of evaluation of the severity of partial discharge is thus improved as a result of backpropagation of the vibration signal, by allowing the vibration signal to be placed on a common time line with respect to the magnetic flux signal and an accurate absolute comparison of the phases thereof to therefore be performed. An indication of the severity of the partial discharge may be included in output 760 of system 700.

It is noted that, as an alternative to backpropagation of the vibration signal to place the vibration signal on a common time scale with the magnetic signal, the magnetic signal may alternatively be forward propagated so as to allow placement thereof on a common time scale with respect to the vibration signal. In this case, the magnetic signal is shifted forwards along the time axis based on a known time taken for the vibration signal to reach the vibration sensor. It is appreciated that in this implementation, knowledge of the time taken for the vibration signal to reach the sensor is required. In contrast, when performing backpropagation until a transform limited pulse is derived, no prior knowledge of the time or distance separation of the sensor from the source is needed.

It is noted that in the example of FIGS. 9A and 9B, the vibration signal is backpropagated over both a distance and a time in order to correct the vibration signal for both for the phase errors and time delay thereof. However, in some cases, the vibration signal may be corrected for only one of these effects rather than both and still be advantageously employed for signal analysis. By way of example, the vibration signal may be corrected for the time delay in the sensing thereof, in order to allow placing the vibration signal on a common time line with the magnetic signal, without necessarily correcting the phase and hence waveform thereof. Further by way of example, the vibration signal may be corrected for the phase accumulated thereby, in order to sharpen the signal, without necessarily correcting the signal for the time delay thereof.

An example of a phase corrected but not time corrected signal is shown in FIGS. 10A-10C. As seen in FIGS. 10A-10C, an acoustic pulse 1002 is measured over a common time period with respect to a magnetic signal 1004. In each of graphs 10A-10C the acoustic pulse is corrected for dispersion effects leading to phase broadening. In FIG. 10A, the acoustic pulse is shown following phase correction and as measured by a sensor at a distance r=4 cm from the location of the partial discharge event by which the acoustic pulse was generated; in FIG. 10B the acoustic pulse is shown as measured by a sensor at a distance r=2 cm from that location and in FIG. 10C the acoustic pulse is shown as generated at the source location itself. It is appreciated that, due to the correction of phase errors, the waveform of the pulse is the same in each of FIGS. 10A-10C, notwithstanding the varying distances from the source location. However, the time at which the pulse is seen to be generated differs between FIGS. 10A-10C, due to the time taken for the acoustic signal to reach the sensor.

In some cases, the dispersion characteristics of the medium or media through which the signal travels en route from source to sensor may be unknown. In general, the dispersion characteristics may vary between different electrical systems and devices, such as between different types of transformers and even different transformers of the same type. In accordance with a preferred embodiment of the present invention, in the case that dispersion of the medium through which the signal travels is unknown, the dispersion may be calibrated in-situ using at least two sensors.

The dispersion calibration process may be based on measuring a phase difference between two sensors mounted at different locations on the monitored device. The Fourier transform of each one of the signals may be found as:

$${F}_{i} ( ω ) = {\int }_{Δ ω} {f}_{i} ( t ) {e}^{- i ω t} dt \qquad ( 7 )$$

where fᵢ(t) is the signal measured in sensor i, and Δω is the analyzed bandwidth. The phase of each of the signals, Φᵢ may then be found. The phase difference accumulated between the two sensors, ΔΦ, results in the broadening of one signal with respect to the other, and in the time delay between them. To find the dispersion relation the phase of each signal may be expanded in series as:

$${Φ}_{i} ≃ {Φ}_{i}^{0} + \frac{\partial {Φ}_{i}^{0}}{\partial ω} Δ ω + \frac{1}{2} \frac{{\partial }^{2} {Φ}_{i}^{0}}{\partial {ω}^{2}} Δ {ω}^{2} + \qquad ( 8 )$$

wherein the first term is a constant phase which may be ignored and the second term is responsible for the time delay between the signals:

$$\frac{\partial {Φ}_{i}^{0}}{\partial ω} = 2 π \frac{{r}_{i}}{{v}_{g}} \qquad ( 9 )$$

where rᵢ is the distance between the source and the i-th sensor, and v_{g} is the group velocity. For example, in an oil power transformer v_{g}˜1.3 km/sec. Thus, the first derivative of phase difference between the two sensors yields the time delay, T, between the signals:

$$\frac{\partial Δ {Φ}^{0}}{\partial ω} = 2 π \frac{Δ r}{{v}_{g}} = 2 π T \qquad ( 10 )$$

The rest of the accumulated phase results in the pulse broadening. Thus, the broadening may be corrected for by compensating over the accumulated phase based on using the phase information from a signal closer to the source.

Finally, the dispersion of the medium may be evaluated using:

$$k ( ω ) = \frac{ΔΦ ( ω )}{Δ r} = \frac{ΔΦ ( ω )}{\frac{{v}_{g} \partial {ΔΦ}^{0}}{2 π \partial ω}} \qquad ( 11 )$$

To compensate for the phase accumulated during propagation which resulted in the pulse broadening, the phase difference between the two sensors without the first order in the series expansion may be used in accordance with:

$$phase compensation = ΔΦ ( ω ) - \frac{\partial Δ {Φ}_{i}^{0}}{\partial ω} Δ ω \qquad ( 12 )$$

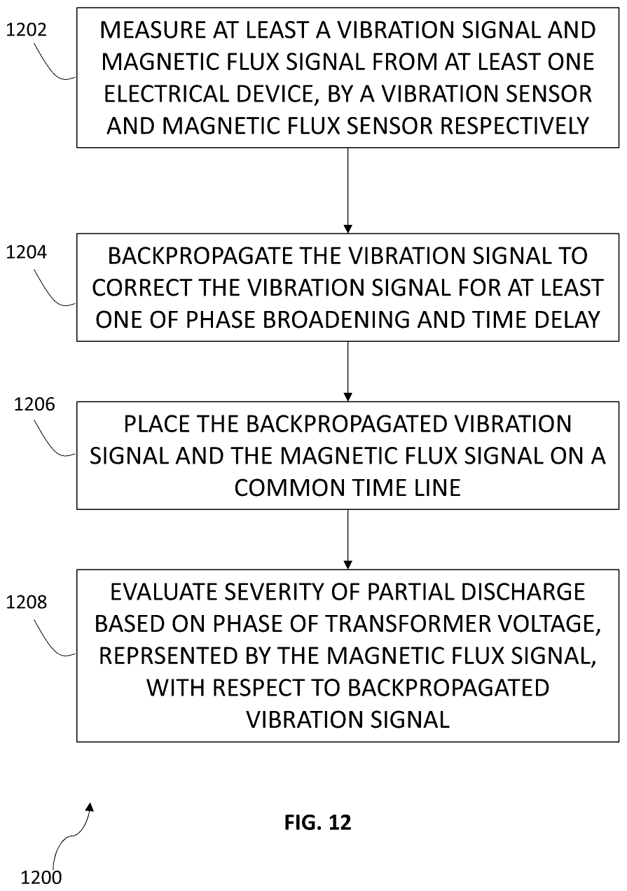

The relationship in FIG. 12 expresses the phenomenon that as a signal propagates a longer distance from the source thereof, the signal expands. As a result, it becomes more difficult to identify the signal's rising edge. By compensating over the extra phase accumulated as the signal travels towards the further of the sensors, the signal sharpens, becoming more similar to the signal measured by the sensor closer to the source, and the time difference between the two signals may be accurately identified and hence the dispersion characteristic of the medium obtained.

Additionally or alternatively to the use of a transformation, such as backpropagation, to allow placing different signals on a common time scale as described with reference to FIGS. 9A and 9B, signal backpropagation may also be used in embodiments of the present invention to create a greater commonality between signals indicative of partial discharge and generated by diverse types of electrical devices.

As described hereinabove, backpropagation of signals may be performed either over a known distance to the fault source or until the signals become transform limited, in order to derive the original signal characteristics. The original signal characteristics may be provided as inputs for the creation of a unified model generally representative of electrical device fault behavior, such as model 110 of FIG. 1. This is based on the understanding that although fault signals manifest themselves very differently depending on the particular high voltage equipment or device within which the fault occurs, the differences in fault manifestation are largely due to characteristics acquired by the fault signal as it travels from the location from which the fault emanates within the device to the sensor at which the signal is measured.

Once the measured signal is converted back to the original signal at its source, differences between signals indicative of faults and generated by different types of high voltage equipment are minimized. By deriving the source signal giving rise to the measured signal, it is possible to identify which types of fault signals have more commonality with the measured signal from any type of relevant high voltage equipment. This enables the training and implementation of a single, unified machine learning algorithm, such as model 110 of FIG. 1, for fault identification and classification applicable to a wide variety of high voltage equipment. At least one of an accuracy and precision of the identified condition of a given electrical device by the application of the unified model may be improved as a result of the use of backpropagation.

In one preferred embodiment of the present invention, signal transformation functionality 720 may be incorporated as a transformative layer in the processing of the output signals from electrical devices, by way of which layer data from various, possibly very different types of electrical devices, may be combined into a unified data set. The transformative layer may unify the diverse data by way of retrieving characteristics of the original signals as generated at the source thereof, thereby reducing or eliminating differences between data arising as a result of signal propagation through different types of electrical devices.

Signal transformation functionality 720 may be incorporated into signal analyzer 130 of FIG. 1 in order to transform signals received from the plurality of devices 102 prior to provision thereof to other signal processing algorithms in signal analyzer 130. By way of example, signal transformation functionality 720 may be incorporated as part of the DSP step shown in FIGS. 2A and 2B. It is understood that signal transformation functionality 720 may be incorporated in system 100 of FIG. 1 and in training and operation of unified model 110 of FIGS. 2A and 2B or as stand-alone functionality, not necessarily combined with the other elements of system 700 of FIG. 7.

Additionally or alternatively to the use of a transformation, such as backpropagation, to allow accurate evaluation of severity of partial discharge and/or to create a greater commonality between signals indicative of partial discharge and generated by diverse types of electrical devices, backpropagation of signals may also be useful in source localization, in accordance with other preferred embodiments of the present invention.

It is appreciated that in systems and methods of the present invention it may be desirable to provide, as a result of monitoring of the electrical device, an output indicative not only of the presence or absence of a fault but also the location of the fault. By way of example, output 160 of FIG. 1, output 210 of FIGS. 2A and 2B, output 330 of FIG. 3 and output 760 of FIG. 7, may include an indication of the location of the partial discharge.

Conventionally, four sensors are required on a device being monitored in order to triangulate the three-dimensional coordinates of the source location, since the following four equations need to be simultaneously solved:

$${( {x}_{1} - {x}_{0} )}^{2} + {( {y}_{1} - {y}_{0} )}^{2} + {( {z}_{1} - {z}_{0} )}^{2} = {( {cT}_{0} )}^{2} \qquad ( 13 )$$

$${( {x}_{2} - {x}_{0} )}^{2} + {( {y}_{2} - {y}_{0} )}^{2} + {( {z}_{2} - {z}_{0} )}^{2} = {( {cT}_{0} + {ct}_{12} )}^{2} \qquad ( 14 )$$

$${( {x}_{3} - {x}_{0} )}^{2} + {( {y}_{3} - {y}_{0} )}^{2} + {( {z}_{3} - {z}_{0} )}^{2} = {( {cT}_{0} + {ct}_{13} )}^{2} \qquad ( 15 )$$

$${( {x}_{4} - {x}_{0} )}^{2} + {( {y}_{4} - {y}_{0} )}^{2} + {( {z}_{4} - {z}_{0} )}^{2} = {( {cT}_{0} + {ct}_{14} )}^{2} \qquad ( 16 )$$

where, (x₀,y₀,z₀) is the discharge source location coordinate, (xᵢ,yᵢ,zᵢ) with i=1-4 are the sensors' respective coordinates, To is the travelling time from the source to the first sensor and t₁ᵢ with i=1-3 is the difference in the arrival time of the acoustic pulse between sensor i and sensor 1.

It is a particular feature of a preferred embodiment of the present invention that the distance to the source r=cT₀ may be found by using backpropagation until the pulse becomes transform limited, since the distance to the source is considered to be that distance over which the pulse becomes transform limited. As a result, equation (13) is solved and one less equation and hence one less sensor is required. The source location of the partial discharge, which corresponds to the fault location, hence may be found using signals from only three sensors on a device.

It is appreciated that source localization using only three sensors as described hereinabove may be useful in a range of monitoring systems in which signals generated at a source in the device being monitored are measured and may be backpropagated in order to find the distance over which the signals become transform limited, which distance may be considered to be the distance to the source. The source localization described hereinabove is thus not limited to use within the systems of the present invention shown in FIGS. 1, 2A, 2B, 3 and 7, although it may be advantageously employed therein.

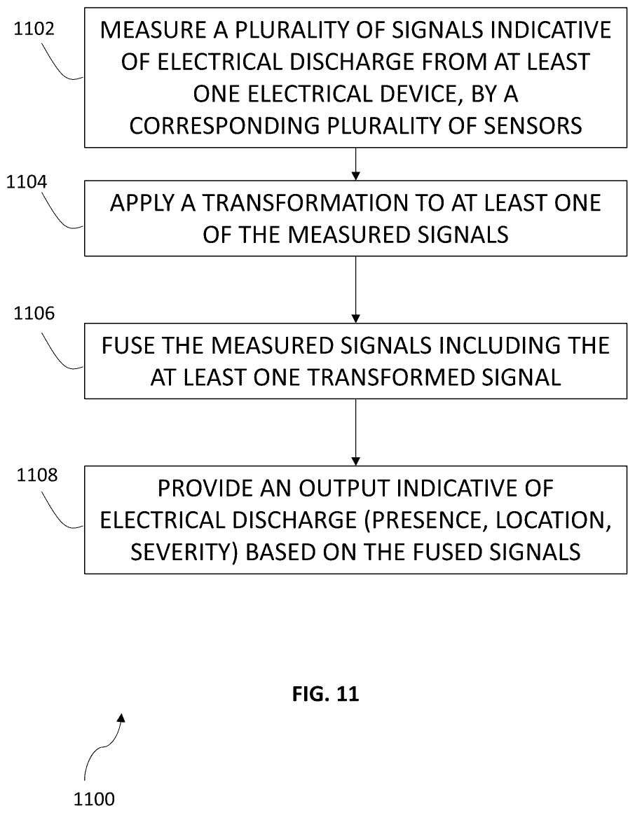

Reference is now made to FIG. 11, which is a simplified flow chart illustrating a method for monitoring of electrical devices, in accordance with a preferred embodiment of the present invention.

As seen in FIG. 11, a method 1100 may begin at a first step 1102, at which a plurality of signals is measured from at least one electrical device by a plurality of sensors. The at least one electrical device is preferably at least one electrical device within which partial discharge may occur and the signals are preferably related to and thus possibly indicative of partial discharge. The at least one electrical device may be a high voltage device, such as a transformer, operating at voltage of at least one kilovolt or an apparent power of at least one MVA. By way of example, high voltage electrical device may operate at voltages in the range of 1-1000 kilovolts and/or at powers of 1-1000 MVA.

As seen at a second step 1104, a transformation is preferably applied to at least one of the measured signals. The transformation may be one of forward propagation, backpropagation over a known distance, backpropagation until transform limitation of the signal and dispersion correction, by way of example. The transformation may serve to increase the commonality between the signals by changing a characteristic of the transformed signal to have a greater commonality with a characteristic of at least one of the other measured signals.

As seen at a third step 1106, the measured signals including the at least one transformed signal are preferably fused and, as seen at a fourth step, the fused signals are preferably used as a basis for providing an indication of partial discharge, which indication may include indication of the presence, location and/or severity of partial discharge. In some embodiments of the present invention, third step 1106 may be followed by additional steps involving automatic or semi-automatic, for example subject to human approval, implementation of steps for remediation of the partial discharge.

Reference is now made to FIG. 12, which is a simplified flow chart illustrating a method for monitoring of electrical devices, in accordance with another preferred embodiment of the present invention. It is appreciated that the method shown in FIG. 12 is one preferred example implementation of the more general method 1100 of FIG. 11.

As seen in FIG. 12, a method 1200 may begin at a first step 1202 at which at least a magnetic flux signal and vibration signal are measured from at least one electrical device. The at least one electrical device is preferably at least one electrical device within which partial discharge may occur and the vibration and magnetic flux signals are preferably related to and thus possibly indicative of partial discharge. The at least one electrical device may be a high voltage device, such as a transformer, operating at voltage of at least one kilovolt or an apparent power of at least one MVA. By way of example, the high voltage electrical device may operate at voltages in the range of 1-1000 kilovolts and/or at powers of 1-1000 MVA.

As seen at a second step 1204, the vibration signal is preferably backpropagated in order to correct the vibration signal for at least one of phase broadening and time delay accrued by the vibration signal as the vibration signal travelled from the source of the partial discharge event by which the signal was generated to the sensor by which the signal was sensed. The vibration signal may be backpropagated over a known distance, in the case that distance to the partial discharge source is known. The vibration signal may alternatively be backpropagated until the vibration signal becomes transform limited. The vibration signal may be corrected for dispersion effects within the medium or media through which the signal travels to reach the sensor.

As seen at a third step 1206, the vibration signal may be placed on a common time line with the magnetic flux signal. It is appreciated that in some embodiments of the present invention, step 1204 may be replaced by an alternative step in which the magnetic flux signal is forward propagated in order to be placed on a common time scale with the vibration signal at step 1206.

As seen at a fourth step 1208, the severity of partial discharge may be evaluated by considering phase of the electrical device voltage, as may be derived based on the magnetic line frequency of the magnetic flux signal, with respect to the backpropagated vibration signal. The lower the voltage at which the vibration pulse indicative of partial discharge is seen to be excited, the greater the severity of the partial discharge. Method 1200 may include additional steps following fourth step 1208 in which an output notification of the severity of the partial discharge is provided and automatic or semi-automatic measures, for example subject to human approval, may be implemented for remediation of the partial discharge.

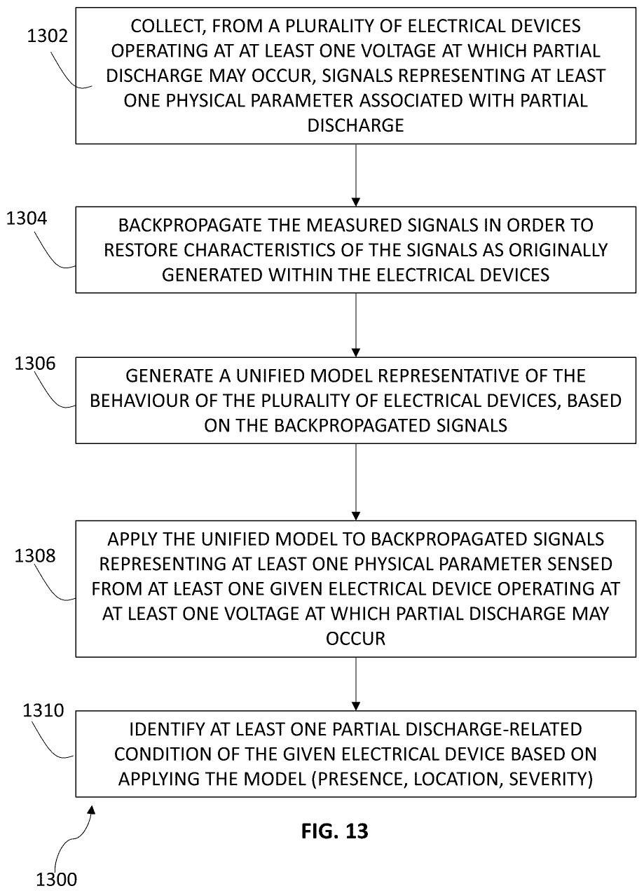

Reference is now made to FIG. 13, which is a simplified flow chart illustrating a method for monitoring of electrical devices, in accordance with another preferred embodiment of the present invention. It is appreciated that the method shown in FIG. 13 is another preferred example implementation of the more general method 1100 of FIG. 11.

As seen in FIG. 13, a method 1300 may begin at a first step 1302 at which signals representing at least one physical parameter associated with partial discharge may be collected by a plurality of sensors from a plurality of electrical devices. The plurality of electrical devices are preferably electrical devices within which partial discharge may occur and the signals are preferably related to and thus possibly indicative of partial discharge. The at least one electrical device may be a high voltage device, such as a transformer, operating at voltage of at least one kilovolt or an apparent power of at least one MVA. The plurality of electrical devices of first step 1302 preferably includes a multiplicity of different types of electrical devices, such as different types of transformers.

As seen at a second step 1304, the measured signals are preferably backpropagated in order to restore characteristics of the signals as the signals were originally generated by partial discharge events within the electrical devices. Backpropagation serves to correct signals for phase broadening and time delays accrued due to propagation of the signals through various media en route to the sensors at which the signals are sensed and thus serves to increase commonality between signals by cancelling out device-specific signal influences. The signals may be backpropagated until a transform limited signal is derived or backpropagated over a known distance to the source of the partial discharge.

As seen at a third step 1306, a unified model may be generated representative of behavior of the plurality of devices and based on the backpropagated signals.

As seen at a fourth step 1308, the unified model may be applied to backpropagated signals representing the at least one physical parameter and sensed from at least one given electrical device operating at a voltage at which partial discharge events may occur.

As seen at a fifth step 1310, at least one partial-discharge related condition of the at least one given electrical device may be identified based on the applying of the unified model.

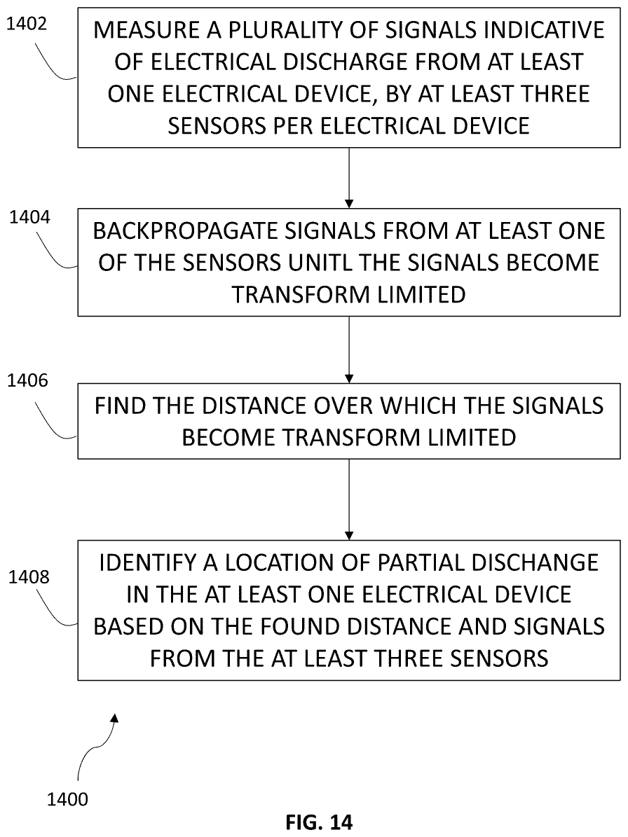

Reference is now made to FIG. 14, which is a simplified flow chart illustrating a method for monitoring of electrical devices, in accordance with yet another preferred embodiment of the present invention. It is appreciated that the method shown in FIG. 14 is yet another preferred example implementation of the more general method 1100 of FIG. 11.

As seen in FIG. 14, a method 1400 may begin at a first step 1402 at which a plurality of signals is measured from at least one electrical device by at least three sensors coupled thereto.

As seen at a second step 1404 signals from at least one of the sensors may be backpropagated until a transform limited signal is derived. The distance over which the signals become transform limited may be found, as seen at a third step 1406, which distance is considered to be indicative of the distance from the sensor to the source of partial discharge in the device.

As seen at a fourth step 1408, a location of the partial discharge may be identified based on signals from the three sensors the distance to the source derived at third step 1406. It is appreciated that method 1400 allows the partial discharge location to be derived based on signals from only three sensors, whereas conventionally at least four sensors are required for this task.

It will be appreciated that the methods of each of FIGS. 11-14 are shown in a highly simplified manner and may include additional or alternative steps. By way of example, signal processing including filtration and feature extraction may be incorporated in the methods. Furthermore, steps in the methods are not necessarily preformed in the order shown and described and may be reordered as appropriate, in accordance with the understanding of one skilled in the art.

It will further be appreciated by persons skilled in the art that the present invention is not limited by what has been particularly claimed hereinbelow. Rather, the scope of the invention includes various combinations and subcombinations of the features described hereinabove as well as modifications and variations thereof as would occur to persons skilled in the art upon reading the forgoing description with reference to the drawings and which are not in the prior art.

1. A method for monitoring and identifying electrical discharge generated by electrical devices comprising:
collecting output indications of at least one physical parameter related to electrical discharge and sensed from a plurality of electrical devices operating at at least one voltage at which electrical discharge may occur;
generating a unified model representative of behavior of said plurality of electrical devices based at least on said output indications of said at least one physical parameter sensed from said plurality of electrical devices;
applying said model to output indications of said at least one physical parameter sensed from at least one given electrical device operating at at least one voltage at which electrical discharge may occur;
identifying, at least by said applying of said model, at least one electrical-discharge related condition of said given electrical device, said identified condition comprising identification of at least one of the presence or absence of electrical discharge, a severity of said electrical discharge if present and a location of said electrical discharge if present; and
automatically providing a human sensible output notification including an indication of said at least one identified condition.

2. A method according to claim 1, wherein said human sensible output notification also comprises a recommendation for adjustment of operating parameters of said at least one given electrical device based on said identified condition, said method further comprising:
automatically adjusting said operating parameters of said given electrical device in accordance with said recommendation, thereby alleviating said electrical discharge.

3. A method according to claim 1, wherein said plurality of electrical devices and said given electrical device comprise high voltage (HV) electrical devices operating at a voltage of at least 1 kilovolt or a power of at least 1 MVA.

4. A method according to claim 1, wherein:
said plurality of electrical devices comprises a multiplicity of mutually different types of electrical devices; and
said unified model is representative of behavior of said mutually different types of electrical devices.

5. A method according to claim 1, and also comprising collecting operational condition data from said plurality of electrical devices and related to electrical discharge, said operational condition data being associated with corresponding ones of said output indications of said sensed physical parameters;
wherein said generating said unified model is additionally based on said operational condition data associated with said output indications of said at least one sensed physical parameter.

6-7. (canceled)

8. A method according to claim 1, wherein:
said electrical discharge comprises partial discharge;
said physical parameter sensed from said plurality of electrical devices is related to partial discharge, said plurality of electrical devices operating at at least one voltage at which partial discharge may occur;
said at least one given electrical device operates at at least one voltage at which partial discharge may occur; and
said identifying comprises identifying, by said applying of said model, at least one partial-discharge related condition of said given electrical device, said identified condition comprising identification of at least one of the presence or absence of partial discharge, a severity of said partial discharge if present and a location of said partial discharge if present.

9. (canceled)

10. A method according to claim 1, wherein said plurality of electrical devices and said at least one given electrical device are selected from a group comprising high power transformers, cables, breakers, switchgears, control equipment, electric panels, motor starters, variable frequency drives and insulators.

11. A method according to claim 1, wherein:
said generating said model comprises extracting, by implementation of cyclostationary analysis, at least one feature of said output indications of said at least one physical parameter of said plurality of electrical devices, said model being based on said at least one feature; and
said applying said model comprises applying said model to at least one feature extracted, by implementation of cyclostationary analysis, from said output indications of said at least one physical parameter sensed from said at least one given electrical device,
an accuracy of said identification of said presence or absence of electrical discharge in said given electrical device being improved due to said implementation of cyclostationary analysis.

12. A method according to claim 11, wherein said output indications of said at least one physical parameter comprise acoustic vibration signals.

13. A method according to claim 1 wherein:
said output indications of said at least one physical parameter comprise signals;
said generating said model comprises backpropagating ones of said signals over respective distances until said signals become transform limited, said model being based at least on said transform limited backpropagated signals; and
said applying said model comprises applying said model to backpropagated, transform limited ones of said signals from said given electrical device,
variation in characteristics of said signals from said plurality of electrical devices and said given electrical device, arising due to propagation of said signals within respective ones of said plurality of electrical devices and said given electrical device, being reduced as a result of said backpropagating,
at least one of an accuracy and precision of said identified condition of said given electrical device being improved thereby.

14-15. (canceled)

16. A method according to claim 1, wherein:
said output indications comprise output indications of vibration and magnetic field; and
said applying said model comprises:
fusing said output indications of said vibration over time and said output indications of said magnetic field over time, and
applying said model to said fused output indications over time,
wherein said output indication of said condition comprises an indication of development of partial discharge based on trends in said fused output indications over time.

17. A method according to claim 16 and also comprising correcting said vibration output indications for dispersion effects due to propagation of said vibration output indications through at least one medium within said at least one electrical device.

18. A method according to claim 16, wherein said applying said model further comprises:
placing, by at least one of backpropagating said vibration output indication and forward propagating said magnetic field output indication, said vibration output indication and said magnetic field output indication on a common timeline;
finding a relative phase of said magnetic field output indication with respect to said vibration output indication along said common timeline; and
evaluating a severity of partial discharge based on said relative phase.

19. (canceled)

20. A method according to claim 18 and also comprising:
finding a distance to a source of said vibration output indication based on said backpropagating said vibration output indication; and
finding a three-dimensional location of said source from which said vibration output indication originated based on output indications sensed by no more than three sensors and taking into account said distance.

21. A method for monitoring and identifying electrical discharge of electrical devices, comprising:
receiving at least first and second signals respectively representing at least first and second physical parameters related to electrical discharge and sensed from at least one electrical device operating at at least one voltage at which electrical discharge may occur;
transforming at least one of said at least first and second signals to generate at least one transformed signal having at least one characteristic in common with said other one of said at least first and second signals;
fusing said first and second signals, wherein at least one of said first and second signals comprises said transformed signal; and
providing a human sensible output indicative of an electrical-discharge related condition of said at least one electrical device, based on said fusing.

22. A method according to claim 21, wherein said transforming comprises at least one of backpropagating and forward propagating.

23. A method according to claim 21, wherein said transforming comprises backpropagating said at least one of said at least first and second signals until said at least one of said at least first and second signals becomes transform limited, and
said at least one characteristic corresponds to a characteristic of said at least one transformed signal as originally generated at a source thereof.

24-25. (canceled)

26. A method according to claim 23, wherein:
said first and second physical parameters comprise vibration and magnetic field;
said transforming comprises backpropagating said vibration signal over a time and a distance until said vibration signal becomes transform limited; and
said fusing comprises:
placing said magnetic field signal and said transform limited vibration signal on a common timeline,
finding a relative phase of said magnetic field signal with respect to said transform limited vibration signal along said common timeline, and
evaluating a severity of electrical discharge based on said relative phase.

27. A method according to claim 26, wherein:
said time at which said vibration signal becomes transform limited corresponds to a time at which said vibration signal was originally generated at said source thereof;
said distance at which said vibration signal becomes transform limited corresponds to a distance between said source and a vibration sensor sensing said vibration signal; and
said human sensible output comprises an indication of a location of electrical discharge in said given electrical device based on said distance to said source.

28-30. (canceled)

31. A system for monitoring and identifying electrical discharge generated by electrical devices comprising:
a plurality of sensors providing output indications of at least one physical parameter related to electrical discharge and sensed from a plurality of electrical devices operating at at least one voltage at which electrical discharge may occur;
a signal analyzer operative to receive said output indications of said at least one physical parameter and to generate, at least based thereon, a unified model representative of behavior of said plurality of electrical devices;
at least one sensor providing at least one output indication of said at least one physical parameter sensed from at least one given electrical device operating at at least one voltage at which electrical discharge may occur;
said signal analyzer being operative to receive said at least one output indication of said at least one physical parameter sensed from said at least one given electrical device and to apply said model thereto;
said signal analyzer being further operative to identify, by the application of said model, at least one electrical-discharge related condition of said given electrical device, said identified condition comprising identification of at least one of the presence or absence of electrical discharge, a severity of said electrical discharge if present and a location of said electrical discharge if present; and
a human-sensible notification module operative to automatically provide a human sensible output notification including an indication of said at least one identified condition.

32-60. (canceled)
